(19) United States
(12) Patent Application Publication
(10) Pub. No.: US 2025/0236554 A1
(43) Pub. Date: Jul. 24, 2025

(54) SURFACE TREATMENT AGENT, ARTICLE, AND PRODUCTION METHOD FOR ARTICLE

(71) Applicant: AGC INC., Tokyo (JP)

(72) Inventors: Koki WATANABE, Tokyo (JP); Motoshi AOYAMA, Tokyo (JP)

(73) Assignee: AGC INC., Tokyo (JP)

(21) Appl. No.: 19/172,954

(22) Filed: Apr. 8, 2025

Related U.S. Application Data
(63) Continuation of application No. PCT/JP2023/036908, filed on Oct. 11, 2023.

(30) Foreign Application Priority Data
Oct. 13, 2022 (JP) 2022-164739

(51) Int. Cl. C03C 17/32

(52) U.S. Cl. CPC C03C 17/32; C03C 2217/78; C03C 2218/10

(57) ABSTRACT

To provide a surface treatment agent from which a surface layer excellent in abrasion resistance can be formed, an article having a surface layer excellent in abrasion resistance, and a method for producing an article. The surface treatment agent of the present invention is a surface treatment agent containing at least one fluorinated ether compound selected from the group consisting of a compound represented by the formula (A1), a compound represented by the formula (A2) and a compound represented by the formula (A3), and an organic solvent containing no fluorine atom.

### TECHNICAL FIELD

The present invention relates to a surface treatment agent, an article and a method for producing an article.

### BACKGROUND ART

The fluorinated ether compound having a fluoropolyether chain and a hydrolysable silyl group is known to be useful for surface treatment of a substrate and to be capable of forming a surface layer having high lubricity, water/oil repellency, etc. on the surface of the substrate. Thus, a surface treatment agent containing such a fluorinated ether compound can be suitably used for applications to which long-term performance of the surface layer is required, for example a member of a touch panel constituting a surface to be touched with fingers, a glasses lens and a display of a wearable terminal.

For example, Patent Document 1 proposes a surface treatment agent containing a predetermined perfluoropolyether group-containing silane compound, as a surface treatment agent for forming a surface treatment layer having water repellency, oil repellency, antifouling property and abrasion resistance on the surface of a substrate.

### PRIOR ART DOCUMENT

### Patent Document

Patent Document 1: WO2017/022437

### DISCLOSURE OF INVENTION

### Technical Problem

In recent years, requirement for performance of a surface layer formed by using a fluorinated ether compound is becoming high. For example, required is a surface layer excellent in performance such that even when formed on a member constituting a surface to be touched with fingers, water/oil repellency is hardly reduced even when repeatedly rubbed with fingers (abrasion resistance).

The present inventors have evaluated a surface layer formed by using a surface treatment agent containing a fluorinated ether compound as described in Patent Document 1 and as a result found that the abrasion resistance of the surface layer can still be improved.

Under these circumstances, the object of the present invention is to provide a surface treatment agent from which a surface layer excellent in abrasion resistance can be formed, an article having a surface layer excellent in abrasion resistance, and a method for producing an article.

### Solution to Problem That is, the present inventors have found that the above object can be achieved by the following construction.

[1] A surface treatment agent containing at least one fluorinated ether compound selected from the group consisting of a compound represented by the formula (A1) described later, a compound represented by the formula (A2) described later and a compound represented by the formula (A3) described later, and an organic solvent containing no fluorine atom.
[2] The surface treatment agent according to [1], wherein
at least one R¹¹ has a carbon chain having 5 or more carbon atoms linked to one another,
at least one of R²¹ and R³¹ has a carbon chain having 5 or more carbon atoms linked to one another, and
at least one R⁴¹ has a carbon chain having 5 or more carbon atoms linked to one another.
   [3] The surface treatment agent according to [1] or [2], wherein
at least one R¹¹ has a carbon chain having 5 to 18 carbon atoms linked to one another,
at least one of R²¹ and R³¹ has a carbon chain having 5 to 18 carbon atoms linked to one another, and
at least one R⁴¹ has a carbon chain having 5 to 18 carbon atoms linked to one another.
   [4] The surface treatment agent according to any one of [1] to [3], wherein
the alkylene group as R¹¹ is a linear alkylene group,
the alkylene group as R²¹ and R³¹ is a linear alkylene group, and
the alkylene group as R⁴¹ is a linear alkylene group.
   [5] The surface treatment agent according to any one of [1] to [4], wherein
the group represented by (OR^{f11})_{y1} has a molecular weight of 2,000 to 10,000,
the group represented by (OR^{f12})_{y2} has a molecular weight of 2,000 to 10,000, and
the group represented by (OR^{f13})_{y3} has a molecular weight of 2,000 to 10,000.
   [6] The surface treatment agent according to any one of [1] to [5], wherein
a ratio of a molecular weight of the group represented by [R^{f1}-(OR^{f11})_{y1}-O-R¹]ⱼ to a molecular weight of the group represented by L¹-(R¹¹-T¹¹)ₓ₁ is 13% or more,
a ratio of a molecular weight of the group represented by R³-(OR^{f12})_{y2}-O-R² to a sum of a molecular weight of the group represented by L²-(R²¹-T²¹)ₓ₂ and a molecular weight of the group represented by (T³¹-R³¹)ₓ₃-L³ is 13% or more, and
a ratio of a sum of a sum of molecular weights of r1 pieces of groups represented by (OR^{f13})_{y3}-O-R⁴ and a molecular weight of the group represented by Q¹, to a sum of molecular weights of r1 pieces of groups represented by L⁴-(R⁴¹-T⁴¹)ₓ₄, is 13% or more.
   [7] The surface treatment agent according to any one of [1] to [6], wherein the organic solvent containing no fluorine atom contains at least one member selected from the group consisting of a ketone-based solvent and an ester-based solvent.
   [8] The surface treatment agent according to any one of [1] to [7], wherein a ratio of a content of the organic solvent containing no fluorine atom to a content of the fluorinated ether compound is 60 to 99.999 mass %.
   [9] An article having a surface layer formed of the surface treatment agent as defined in any one of [1] to [8] on the surface of a substrate.
   [10] A method for producing an article, which comprises forming a surface layer using the surface treatment agent as defined in any one of [1] to [8] by dry coating method or wet coating method.

### Advantageous Effects of Invention

According to the present invention, provided are a surface treatment agent from which a surface layer excellent in abrasion resistance can be formed, an article having a surface layer excellent in abrasion resistance, and a method for producing an article.

### DESCRIPTION OF EMBODIMENTS

In this specification, a group represented by the formula (g1) may sometimes be referred to as group (g1). A compound represented by the formula (A1) may sometimes be referred to as Compound (A1). The same applies to compounds etc. represented by other formulae.

A “fluoroalkyl group” generically means a perfluoroalkyl group and a partial fluoroalkyl group. The perfluoroalkyl group means an alkyl group in which all hydrogen atoms are replaced with fluorine atoms. The partial fluoroalkyl group means an alkyl group in which 1 or more hydrogen atoms are replaced with fluorine atoms and which has 1 or more hydrogen atoms. That is, the fluoroalkyl group is an alkyl group having 1 or more fluorine atoms.

A “reactive silyl group” generically means a hydrolysable silyl group and a silanol group (Si—OH), and the “hydrolysable silyl group” means a group capable of forming a silanol group when hydrolyzed.

An “organic group” means a hydrocarbon group which may have a substituent and which may have a hetero atom or another bond in a carbon chain.

A “hydrocarbon group” is a group composed of carbon atoms and hydrogen atoms and is an aliphatic hydrocarbon group (for example, a bivalent aliphatic hydrocarbon group may be a linear alkylene group, an alkylene group having a branch or a cycloalkylene group), an aromatic hydrocarbon group (for example, a bivalent aromatic hydrocarbon group may be a phenylene group) or a combination thereof.

A “surface layer” means a layer to be formed on the surface of a substrate.

A “molecular weight” of a fluoropolyether chain and a fluorinated ether compound is a number average molecular weight calculated from the number (average) of oxyfluoroalkylene units based on the terminal groups by means of ¹H-NMR and ¹⁹F-NMR.

A molecular weight of another partial structure of the fluorinated ether compound other than the fluoropolyether chain may be calculated by conducting structural analysis of the fluorinated ether compound by means of ¹H-NMR and ¹⁹F-NMR.

“to” representing a range of numerical values means to include numerical values before and after it as the lower limit value and the upper limit value.

### Surface Treatment Agent

The surface treatment agent of the present invention (hereinafter sometimes referred to as “present treatment agent”) contains at least one fluorinated ether compound selected from the group consisting of a compound represented by the formula (A1) described later, a compound represented by the formula (A2) described later and a compound represented by the formula (A3) described later, and an organic solvent containing no fluorine atom (hereinafter sometimes referred to as “non-fluorinated organic solvent”).

The present treatment agent is capable of forming a surface layer excellent in abrasion resistance on the surface of a substate. The detailed mechanism has not been clearly understood yet, but is estimated as follows.

In the fluorinated ether compound represented by the formula (A1), (A2) or (A3), when an organic group containing a reactive silyl group other than the fluoropolyether chain has a molecular weight of a predetermined value or more, in formation of the surface layer, the organic group highly compatible with the non-fluorinated organic solvent, is likely to be unevenly present on the side of the non-fluorinated organic solvent that is attached to the surface of the substrate, as compared with the fluoropolyether chain. As a result, orientation of the fluorinated ether compound is promoted, and the surface layer to be formed has improved abrasion resistance.

Now, the respective components contained in the present treatment agent will be described.

### Fluorinated Ether Compound

The present treatment agent contains at least one fluorinated ether compound selected from the group consisting of a compound represented by the following formula (A1), a compound represented by the following formula (A2) and a compound represented by the following formula (A3).

Hereinafter the Compound (A1), the Compound (A2) and the Compound (A3) may sometimes be referred to generally as “the present compound”.

[R^{f1}-(OR^{f11})_{y1}-O-R¹]ⱼ-L¹-(R¹¹-T¹¹)ₓ₁ (A1)

(T³¹-R³¹)ₓ₃-L³-R³-(OR^{f12})_{y2}-O-R²-L²-(R²¹-T²¹)ₓ₂ (A2)

Q¹[-(OR^{f13})_{y3}-O-R⁴-L⁴-(R⁴¹-T⁴¹)ₓ₄]ᵣ₁ (A3)

In the formula (A1),
R^{f1} is a C₁₋₂₀ fluoroalkyl group, and when there is a plurality of R^{f1}, the plurality of R^{f1} may be the same or different from each other,
R^{f11} is a C₁₋₆ fluoroalkylene group, and when there is a plurality of R^{f11}, the plurality of R^{f11} may be the same or different from each other,
R¹ is an alkylene group or a fluoroalkylene group, and when there is a plurality of R¹, the plurality of R¹ may be the same or different from each other,
L¹ is a single bond or a (j+x1)-valent group which may have N, O, S or Si and may have a branch point, and in which atoms bonded to R¹ and R¹¹ are each independently N, O, S, Si, a carbon atom constituting the branch point, or a carbon atom having a hydroxy group or an oxo group (═O),
R¹¹ is an alkylene group in which an atom bonded to L¹ may be an etheric oxygen atom, and which may have an etheric oxygen atom between carbon atoms, and when there is a plurality of R¹¹, the plurality of R¹¹ may be the same or different from each other,
T¹¹ is a group represented by -SiR^{a11}_{z11}R^{a12}_{3-z11}, and when there is a plurality of T¹¹, the plurality of T¹¹ may be the same or different from each other,
R^{a11} is a hydroxy group or a hydrolysable group, and when there is a plurality of R^{a11}, the plurality of R^{a11} may be the same or different from each other,
R^{a12} is a non-hydrolysable group, and when there is a plurality of R^{a12}, the plurality of R^{a12} may be the same or different from each other,
j is an integer of 1 or more, and when j is 1, y1 is an integer of 2 or more, or R¹ is a fluoroalkylene group,
z11 is an integer of 1 to 3,
x1 is an integer of 1 or more,
y1 is an integer of 1 or more, and when there is a plurality of y1, the plurality of y1 may be the same or different from each other, and
the group represented by L¹-(R¹¹-T¹¹)ₓ₁ has a molecular weight of 600 or more.

In the formula (A2),
R^{f12} is a C₁₋₆ fluoroalkylene group, and when there is a plurality of R^{f12}, the plurality of R^{f12} may be the same or different from each other,
R² and R³ are each independently an alkylene group or a fluoroalkylene group,
L² is a single bond or a (1+x2)-valent group which may have N, O, S or Si and may have a branch point, and in which atoms bonded to R² and R²¹ are each independently N, O, S, Si, a carbon atom constituting the branch point, or a carbon atom having a hydroxy group or an oxo group (═O),
L³ is a single bond or a (1+x3)-valent group which may have N, O, S or Si and may have a branch point, and in which atoms bonded to R³ and R³¹ are each independently N, O, S, Si, a carbon atom constituting the branch point, or a carbon atom having a hydroxy group or an oxo group (═O),
R²¹ is an alkylene group in which an atom adjacent to L² may be an etheric oxygen atom, and which may have an etheric oxygen atom between carbon atoms, and when there is a plurality of R²¹, the plurality of R²¹ may be the same or different from each other,
R³¹ is an alkylene group in which an atom adjacent to L³ may be an etheric oxygen atom, and which may have an etheric oxygen atom between carbon atoms, and when there is a plurality of R³¹, the plurality of R³¹ may be the same or different from each other,
T²¹ and T³¹ are each independently -SiR^{a21}_{z21}R^{a22}_{3-z21}, when there is a plurality of T²¹, the plurality of T²¹ may be the same or different from each other, and when there is a plurality of T³¹, the plurality of T³¹ may be the same or different from each other,
R^{a21} is a hydroxy group or a hydrolysable group, and when there is a plurality of R^{a21}, the plurality of R^{a21} may be the same or different from each other,
R^{a22} is a non-hydrolysable group, and when there is a plurality of R^{a22}, the plurality of R^{a22} may be the same or different from each other,
z21 is an integer of 1 to 3,
x2 and x3 are each independently an integer of 1 or more,
y2 is an integer of 1 or more, and when y2 is 1, R² is a fluoroalkylene group, and
the molecular weight of at least one of the group represented by L²-(R²¹-T²¹)ₓ₂ and the group represented by (T³¹-R³¹)ₓ₃-L³ is 600 or more.

In the formula (A3),
Q¹ is a r1-valent group having a branch point,
R^{f13} is a C₁₋₆ fluoroalkylene group, and when there is a plurality of R^{f13}, the plurality of R^{f13} may be the same or different from each other,
R⁴ is each independently an alkylene group or a fluoroalkylene group, and the plurality of R⁴ may be the same or different from each other,
L⁴ is a single bond or a (1+x4)-valent group which may have N, O, S or Si and may have a branch point, and in which atoms bonded to R⁴ and R⁴¹ are each independently N, O, S, Si, a carbon atom constituting the branch point, or a carbon atom having a hydroxy group or an oxo group (═O), and the plurality of L⁴ may be the same or different from each other,
R⁴¹ is an alkylene group in which an atom adjacent to L⁴ may be an etheric oxygen atom, and which may have an etheric oxygen atom between carbon atoms, and the plurality of R⁴¹ may be the same or different from each other,
T⁴¹ is -SiR^{a41}_{z41}R^{a42}_{3-z41}, and the plurality of T⁴¹ may be the same or different from each other,
R^{a41} is a hydroxy group or a hydrolysable group, and the plurality of R^{a41} may be the same or different from each other,
R^{a42} is a non-hydrolysable group, and when there is a plurality of R^{a42}, the plurality of R^{a42} may be the same or different from each other,
z41 is an integer of 1 to 3,
x4 is an integer of 1 or more, and when there is a plurality of x4, the plurality of x4 may be the same or different from each other,
y3 is an integer of 1 or more, and when there is a plurality of y3, the plurality of y3 may be the same or different from each other,
r1 is 3 or 4, and
at least one group represented by L⁴-(R⁴¹-T⁴¹)ₓ₄ has a molecular weight of 600 or more.

Since the present compound has a fluoropolyether chain, a surface layer formed by using the present compound is excellent in water/oil repellency and fingerprint stain removability. Further, since the present compound has a reactive silyl group, which is firmly chemically bonded to a substrate, a surface layer formed by using the present compound is excellent in durability such as abrasion resistance. Thus, the present compound is suitably used as a surface treatment agent for forming a surface layer which imparts water/oil repellency, abrasion resistance and fingerprint stain removability to the surface of a substrate.

Now, structures of the respective compounds will be described. Symbols with same structures can be indicated as such and appropriately referenced.

The present compound has a fluoropolyether chain, which is a group having 2 or more oxyfluoroalkylene units.

Such a fluoropolyether chain may have a hydrogen atom. In order that an obtainable surface layer will be more excellent in abrasion resistance and fingerprint stain removability, the proportion of fluorine atoms represented by the following formula (I) in the fluoropolyether chain is preferably 60% or more, more preferably 80% or more, further preferably substantially 100%, that is the fluoropolyether chain is a perfluoropolyether chain. When the proportion of fluorine atom is 60% or more, the fluorine amount in the fluoropolyether chain is large, and lubricity and fingerprint removability will more improve.

Formula (I): proportion of fluorine atoms (%)=(number of fluorine atoms)/{(number of fluorine atoms)+(number of hydrogen atoms)}×100

The molecular weight of the group represented by (OR^{f11})_{y1}, the molecular weight of the group represented by (OR^{f12})_{y2}, and the molecular weight of the group represented by (OR^{f13})_{y3} are, in order that the obtainable surface layer has both fingerprint stain removability and lubricity, preferably 1,000 to 20,000, more preferably 1,500 to 15,000, further preferably 2,000 to 10,000. When the molecular weight of the above group is 1,000 or more, the fluoropolyether chain has improved flexibility and in addition, the fluorine amount in the molecule is large, whereby lubricity and fingerprint removability will further improve. On the other hand, when the molecular weight of the above group is 20,000 or less, the obtainable surface layer will be more excellent in abrasion resistance.

### Compound (A1)

The Compound (A1) has a structure represented by the following formula (A1).

[R^{f1}-(OR^{f11})_{y1}-O-R¹]ⱼ-L¹-(R¹¹-T¹¹)ₓ₁ (A1)

Symbols in the formula (A1) are as defined above.

R^{f1} is a C₁₋₂₀ fluoroalkyl group. The fluoroalkyl group may be linear, or may have a branch and/or a cyclic structure. In view of abrasion resistance, it is preferably a linear fluoroalkyl group, and in view of easiness of synthesis, etc., the number of carbon atoms in the fluoroalkyl group is preferably 1 to 6, more preferably 1 to 3.

R^{f11} is a C₁₋₆ fluoroalkylene group, and when there is a plurality of R^{f11}, the plurality of R^{f11} may be the same or different from each other. In (OR^{f11})_{y1}, y1 is an integer of 1 or more and is preferably 1 to 200, more preferably 2 to 200.

(OR^{f11})_{y1} preferably has a structure represented by the following formula (G11).

-[(OG^{f1})ₘ₁(OG^{f2})ₘ₂(OG^{f3})ₘ₃(OG^{f4})ₘ₄(OG^{f5})ₘ₅(OG^{f6})ₘ₆]- (G11)
wherein
G^{f1} is a fluoroalkylene group having 1 carbon atom,
G^{f2} is a fluoroalkylene group having 2 carbon atoms,
G^{f3} is a fluoroalkylene group having 3 carbon atoms,
G^{f4} is a fluoroalkylene group having 4 carbon atoms,
G^{f5} is a fluoroalkylene group having 5 carbon atoms,
G^{f6} is a fluoroalkylene group having 6 carbon atoms,
m1, m2, m3, m4, m5 and m6 are each independently an integer of 0 or 1 or more, and m1+m2+m3+m4+m5+m6 is preferably an integer of 1 to 200.

In the formula (G11), the order of binding of (OG^{f1}) to (OG^{f6}) is optional. m1 to m6 in the formula (G11) respectively means the numbers of (OG^{f1}) to (OG^{f6}), not the arrangement. For example, (OG^{f5})ₘ₅ means that the number of (OG^{f5}) is m5, not a block arranged structure of (OG^{f5})ₘ₅. Likewise, the order of description of (OG^{f1}) to (OG^{f6}) does not represent the order of binding of the respective units.

The fluoroalkylene group having 3 to 6 carbon atoms may be a linear fluoroalkylene group, or may be a fluoroalkylene group having a branch or a cyclic structure.

Specific examples of G^{f1} include —CF₂—, and —CHF—.

Specific examples of G^{f2} include —CF₂CF₂—, —CHFCF₂—, —CHFCHF—, —CH₂CF₂—, and —CH₂CHF—.

Specific examples of G^{f3} include —CF₂CF₂CF₂—, —CF₂CHFCF₂—, —CF₂CH₂CF₂—, —CHFCF₂CF₂—, —CHFCHFCF₂—, —CHFCHFCHF—, —CHFCH₂CF₂—, —CH₂CF₂CF₂—, —CH₂CHFCF₂—, —CH₂CH₂CF₂—, —CH₂CF₂CHF—, —CH₂CHFCHF—, —CH₂CH₂CHF—, —CF(CF₃)—CF₂—, —CF(CHF₂)—CF₂—, —CF(CH₂F)—CF₂—, —CF(CH₃)—CF₂—, —CF(CF₃)—CHF—, —CF(CHF₂)—CHF—, —CF(CH₂F)—CHF—, —CF(CH₃)—CHF—, —CF(CF₃)—CH₂—, —CF(CHF₂)—CH₂—, —CF(CH₂F)—CH₂—, —CF(CH₃)—CH₂—, —CH(CF₃)—CF₂—, —CH(CHF₂)—CF₂—, —CH(CH₂F)—CF₂—, —CH(CH₃)—CF₂—, —CH(CF₃)—CHF—, —CH(CHF₂)—CHF—, —CH(CH₂F)—CHF—, —CH(CH₃)—CHF—, —CH(CF₃)—CH₂—, —CH(CHF₂)—CH₂—, and —CH(CH₂F)—CH₂—.

Specific examples of G^{f4} include —CF₂CF₂CF₂CF₂—, —CHFCF₂CF₂CF₂—, —CH₂CF₂CF₂CF₂—, —CF₂CHFCF₂CF₂—, —CHFCHFCF₂CF₂—, —CH₂CHFCF₂CF₂—, —CF₂CH₂CF₂CF₂—, —CHFCH₂CF₂CF₂—, —CH₂CH₂CF₂CF₂—, —CHFCF₂CHFCF₂—, —CH₂CF₂CHFCF₂—, —CF₂CHFCHFCF₂—, —CHFCHFCHFCF₂—, —CH₂CHFCHFCF₂—, —CF₂CH₂CHFCF₂—, —CHFCH₂CHFCF₂—, —CH₂CH₂CHFCF₂—, —CF₂CH₂CH₂CF₂—, —CHFCH₂CH₂CF₂—, —CH₂CH₂CH₂CF₂—, —CHFCH₂CH₂CHF—, —CH₂CH₂CH₂CHF— and -cycloC₄F₆—.

Specific examples of G^{f5} include —CF₂CF₂CF₂CF₂CF₂—, —CHFCF₂CF₂CF₂CF₂—, —CH₂CHFCF₂CF₂CF₂—, —CF₂CHFCF₂CF₂CF₂—, —CHFCHFCF₂CF₂CF₂—, —CF₂CH₂CF₂CF₂CF₂—, —CHFCH₂CF₂CF₂CF₂—, —CH₂CH₂CF₂CF₂CF₂—, —CF₂CF₂CHFCF₂CF₂—, —CHFCF₂CHFCF₂CF₂—, —CH₂CF₂CHFCF₂CF₂—, —CH₂CF₂CF₂CF₂CH₂—, and -cycloC₅F₈—.

Specific examples of G^{f6} include —CF₂CF₂CF₂CF₂CF₂CF₂—, —CF₂CF₂CHFCHFCF₂CF₂—, —CHFCF₂CF₂CF₂CF₂CF₂—, —CHFCHFCHFCHFCHFCHF—, —CHFCF₂CF₂CF₂CF₂CH₂—, —CH₂CF₂CF₂CF₂CF₂CH₂—, and -cycloC₆F₁₀—.

-cycloC₄F₆— means a perfluorocyclobutanediyl group, and its specific examples include a perfluorocyclobutene-1,2-diyl group. -cycloC₅F₈— means a perfluorocyclopentanediyl group and its specific examples include a perfluorocyclopentan-1,3-diyl group. -cycloC₆F₁₀— means a perfluorocyclohexanediyl group and its specific examples include a perfluorocyclohexan-1,4-diyl group.

(OR^{f11})_{y1} particularly preferably has a structure represented by any one of the following formulae (G2) to (G4), in view of more excellent water/oil repellency, abrasion resistance and fingerprint stain removability.

(OG^{f1})ₘ₁-(OG^{f2})ₘ₂ formula (G2)

(OG^{f2})ₘ₂-(OG^{f4})ₘ₄ formula (G3)

(OG^{f3})ₘ₃ formula (G4)

Symbols in the formulae (G2) to (G4) are as defined for the above formula (G11).

In the formulae (G2) and (G3), the orders of binding of (OG^{f1}) and (OG^{f2}), and (OG^{f2}) and (OG^{f4}), are respectively optional. For example, in the formula (G2), (OG^{f1}) and (OG^{f2}) may alternately be arranged, (OG^{f1}) and (OG^{f2}) may be arranged respectively in blocks, or may be randomly arranged.

In the formula (G2), m1 is preferably 1 to 30, more preferably 1 to 20. m2 is preferably 1 to 30, more preferably 1 to 20.

In the formula (G3), m2 is preferably 1 to 30, more preferably 1 to 20. m4 is preferably 1 to 30, more preferably 1 to 20.

In the formula (G4), m3 is preferably 1 to 30, more preferably 1 to 20.

In (OR^{f11})_{y1}, the proportion of fluorine atoms [{number of fluorine atoms/(number of fluorine atoms+number of hydrogen atoms)}×100 (%)] is, in view of excellent water/oil repellency and fingerprint removability, preferably 60% or more, more preferably 70% or more, further preferably 80% or more. The upper limit is for example 99.99%.

A preferred range of the molecular weight of the group represented by (OR^{f11})_{y1} is as described above.

R¹ is an alkylene group or a fluoroalkylene group. The alkylene group and fluoroalkylene group as R¹ may be linear or may have a branch and/or a cyclic structure. In view of easiness of synthesis, etc., preferred is an alkylene group or a fluoroalkylene group that is linear or that has a branch, more preferred is an alkylene group or a fluoroalkylene group that is linear or that has a methyl group or a fluoromethyl group as a branch. The number of carbon atoms in R¹ is preferably 1 to 30, more preferably 1 to 20, further preferably 1 to 10, particularly preferably 1 to 6. In a case where j is 1 and L¹ is a single bond, R¹ is bonded to R¹¹. In such a case, the carbon atom in R¹, bonded to R¹¹, is bonded to at least one fluorine atom or fluoroalkyl group.

j represents the number of [R^{f1}-(OR^{f11})_{y1}-O-R¹] in one molecule and is an integer of 1 or more, preferably 1 to 20, more preferably 1 to 10, further preferably 1 to 4.

In a case where j is 1, y1 is an integer of 2 or more, or R¹ is a fluoroalkylene group.

R¹¹ is an alkylene group in which the atom bonded to L¹ may be an etheric oxygen atom, and which may have an etheric oxygen atom between carbon atoms.

The alkylene group as R¹¹ may be linear, or may have a branch and/or a cyclic structure. It is preferably an alkylene group that is linear or that has a branch, more preferably a linear alkylene group, whereby the Compound (A1) will densely be arranged when forming a surface layer.

The alkylene group as R¹¹ preferably has a carbon chain having 5 or more carbon atoms linked to one another, whereby the obtainable surface layer will be more excellent in water/oil repellency and fingerprint stain removability and also excellent in durability such as abrasion resistance.

“Having a carbon chain having 5 or more carbon atoms linked to one another” means that R¹¹ has an alkylene group having 5 or more carbon atoms. In the case of an alkylene group having a branch and/or a cyclic structure, carbon atoms in the branch and the cyclic structure are included. Specifically, for example, —CH₂CH₂CH(—CH₂CH₃)—CH₂CH₂CH₂CH₂— has a carbon chain having 9 carbon atoms linked including carbon atoms in the branch.

The alkylene group as R¹¹ more preferably has a carbon chain having 9 or more carbon atoms linked to one another, further preferably has a carbon chain having 11 or more carbon atoms linked to one another. By the alkylene group having a carbon chain having the above number of carbon atoms linked to one another, being adjacent to the hydrolysable silyl group, the obtainable surface layer has more improved abrasion resistance.

The upper limit of the number of carbon atoms is not particularly limited, and in view of more excellent water/oil repellency and fingerprint stain removability, the number of carbon atoms is preferably 20 or less, more preferably 18 or less.

Particularly, R¹¹ is preferably a C₅₋₁₈ linear alkylene group, more preferably a C₁₁₋₁₈ linear alkylene group.

R¹¹ is specifically represented by the following formula (g2).

*-(O)ₐ₁-(R^{g2}O)ₐ₂—R^{g2}-** (g2)
wherein R^{g2} is an alkylene group having 1 or more carbon atoms, and the plurality of R^{g2} if any may be the same or different from each other,
a1 is 0 or 1,
a2 is an integer of 0 or more,
* is a binding site bonded to L¹, and
** is a binding site bonded to T¹¹,
provided that in a case where L¹ is a single bond, R¹¹ is directly bonded to R¹.

When a1 is 0, the atom having the binding site * is a carbon atom, and when a1 is 1, the atom having the binding site * is an oxygen atom. In the Compound (A1), a1 may be either 0 or 1 and is properly selected depending upon e.g. the synthesis.

a2 represents the number of repetition of R^{g2}O and in view of durability of the obtainable surface layer, is preferably 0 to 6, more preferably 0 to 3, further preferably 0 to 1.

The alkylene group as R^{g2} is the same as the alkylene group as R¹¹, and its preferred embodiment is also the same.

R¹¹ is further preferably a group represented by the following formula (g3), whereby the obtainable surface layer is more excellent in water/oil repellency and fingerprint stain removability and is also excellent in durability such as abrasion resistance.

*-(O)ₐ₁-R^{g3}-** (g3)
wherein R^{g3} is an alkylene group, and
a1, * and ** are as defined for the formula (g2).

The alkylene group as R^{g3} is the same as the alkylene group as R¹¹, and its preferred embodiment is also the same.

T¹¹ is a group represented by -SiR^{a11}_{z11}R^{a12}_{3-z11},
wherein R^{a11} is a hydroxy group or a hydrolysable group, and when there is a plurality of R^{a11}, the plurality of R^{a11} may be the same or different from each other,
R^{a12} is a non-hydrolysable group, and when there is a plurality of R^{a12}, the plurality of R^{a12} may be the same or different from each other, and
z11 is an integer of 1 to 3.

In a case where R^{a11} is a hydroxy group, it constitutes a silanol (Si—OH) group with the Si atom. The hydrolysable group is a group to be a hydroxy group (that is a silanol group) when hydrolyzed. The silanol group further undergoes intermolecular reaction to form a Si—O—Si bond. The silanol group undergoes a dehydration condensation reaction with a hydroxy group on the surface of a substrate (substrate-OH) to form a chemical bond (substrate-O—Si). The Compound (A1), which has 1 or more T^{a11}, impart excellent abrasion resistance to the formed surface layer.

The hydrolysable group as R^{a11} may, for example, be an alkoxy group, an aryloxy group, a halogen atom, an acyl group, an acyloxy group or an isocyanate group (—NCO). The alkoxy group is preferably a C₁₋₄ alkoxy group. The acyl group is preferably a C₁₋₆ acyl group. The acyloxy group is preferably a C₁₋₆ acyloxy group.

The hydrolysable group as R^{a11} is, in view of easiness of production of the Compound (A1), preferably a C₁₋₄ alkoxy group or a halogen atom. The alkoxy group as R^{a11} is preferably a C₁₋₄ alkoxy group, whereby the Compound (A1) will be excellent in storage stability and outgassing at the time of reaction is suppressed, particularly preferably an ethoxy group in view of long-term storage stability, and particularly preferably a methoxy group in view of a short hydrolysis time. The halogen atom is preferably a chlorine atom.

The non-hydrolysable group as R^{a12} may, for example, be a hydrogen atom or a monovalent hydrocarbon group.

The hydrocarbon group may, for example, be an alkyl group, a cycloalkyl group, an alkenyl group or an allyl group, and the hydrocarbon group may be substituted by fluorine. In view of easiness of production, the hydrocarbon group is preferably an alkyl group. In view of easiness of production, the number of carbon atoms in the hydrocarbon group is preferably 1 to 6, more preferably 1 to 3, further preferably 1 to 2.

z11 is an integer of 1 to 3, and in view of adhesion to a substrate, preferably 2 or 3, more preferably 3.

Specific examples of T¹¹ include —Si(OCH₃)₃, —SiCH₃(OCH₃)₂, —Si(OCH₂CH₃)₃, —SiCl₃, —Si(OCOCH₃)₃, —Si(NCO)₃, and —Si(OCH₂CF₃)₃. In view of handling efficiency in production, preferred is —Si(OCH₃)₃.

When there is a plurality of T¹¹ in one molecule, the plurality of T¹¹ may be the same or different from each other.

x1 represents the number of (R¹¹-T¹¹) in one molecule and is an integer of 1 or more, preferably 1 to 32, more preferably 1 to 18, further preferably 2 to 12.

L¹ is a single bond or a (j+x1)-valent group which may have N, O, S or Si and may have a branch point, and in which the atoms bonded to R¹ and R¹¹ are each independently N, O, S, Si, a carbon atom constituting the branch point, or a carbon atom having a hydroxy group or an oxo group (═O). The atom bonded to R¹ and the atom bonded to R¹¹ may be the same atom or may be different atoms.

In a case where L¹ is a single bond, R¹ and R¹¹ in the formula (A1) are directly bonded, and the Compound (A1) is represented by the following formula (A1′).

R^{f1}-(OR^{f11})_{y1}-O-R¹-R¹¹-T¹¹ (A1′)

Symbols in the formula (A1′) are as defined for the formula (A1).

In a case where L¹ is a trivalent or higher valent group, L¹ has at least one type of branch point (hereinafter referred to as “branch point P¹”) selected from the group consisting of C, N, Si, a cyclic structure and a (j+x1)-valent organopolysiloxane residue.

In a case where the branch point P¹ is N, the branch point P¹ is represented, for example, by *-N(-**)₂ or (*-)₂N-**. * is a binding site on the R¹ side, and ** is a binding site on the R¹¹ side.

In a case where the branch point P¹ is C, the branch point P¹ is represented, for example, by *-C(-**)₃, (*-)₂C(-**)₂, (*-)₃C-**, *-CR²⁹(-**)₂, or (*-)₂CR²⁹-**. * is a binding site on the R¹ side, ** is a binding site on the R¹¹ side, and R²⁹ is a monovalent group and may, for example, be a hydrogen atom, a hydroxy group, a hydrocarbon group, or an alkoxy group. The hydrocarbon group may be an aliphatic hydrocarbon group such as a linear alkyl group, an alkyl group having a branch or a cycloalkyl group, an aromatic hydrocarbon group such as a phenyl group, or a combination thereof.

In a case where the branch point P¹ is Si, the branch point P¹ is represented, for example, by *-Si(-**)₃, (*-)₂Si(-**)₂, (*-)₃Si-**, *-SiR²⁹(-**)₂, or (*-)₂SiR²⁹-**. * is a binding site on the R¹ side, ** is a binding site on the R¹¹ side, and R²⁹ is a monovalent group and may, for example, be a hydrogen atom, a hydroxy group, a hydrocarbon group, or an alkoxy group. The hydrocarbon group may be an aliphatic hydrocarbon group such as a linear alkyl group, an alkyl group having a branch or a cycloalkyl group, an aromatic hydrocarbon group such as a phenyl group, or a combination thereof.

The cyclic structure constituting the branch point P¹ is preferably at least one member selected from the group consisting of a 3- to 8-membered aliphatic ring, a 3- to 8-membered aromatic ring, a 3- to 8-membered heterocyclic ring and a condensed ring of 2 or more of such rings, more preferably a cyclic structure of any of the following formulae, in view of easiness of production of the Compound (A1) and whereby the obtainable surface layer will be more excellent in abrasion resistance, light resistance and chemical resistance. The cyclic structure may have a substituent such as a halogen atom, an alkyl group (which may have an etheric oxygen atom between carbon atoms), a cycloalkyl group, an alkenyl group, an allyl group, an alkoxy group or an oxo group (═O).

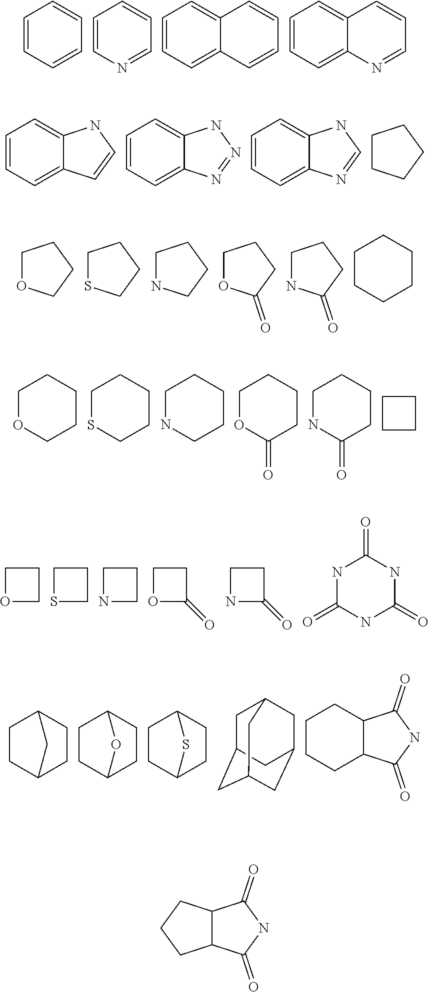

As the organopolysiloxane residue constituting the branch point P¹, the following groups may, for example, be mentioned. In the following formulae, R²⁵ is a hydrogen atom, an alkyl group, an alkoxy group or a phenyl group. The number of carbon atoms in the alkyl group or the alkoxy group as R²⁵ is preferably 1 to 10, more preferably 1. The plurality of R²⁵ may be the same or different from each other.

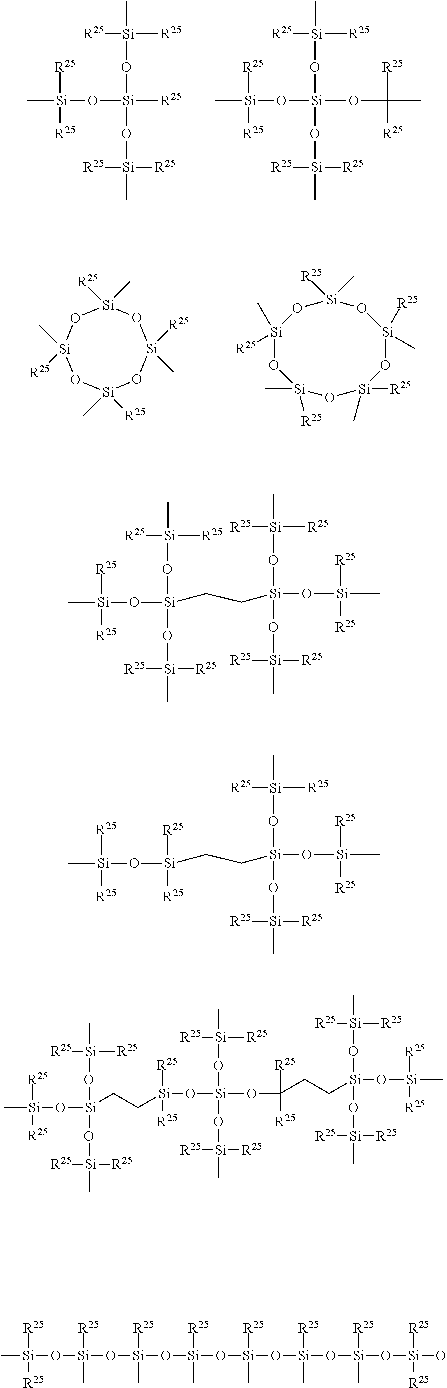

Bivalent or higher valent L¹ may have at least one bond selected from the group consisting of —C(O)N(R²⁶)—, —N(R²⁶)C(O)—, —C(O)O—, —OC(O)—, —C(O)—, —C(OH)—, —O—, —N(R²⁶)—, —S—, —OC(O)O—, —NHC(O)O—, —OC(O)NH—, —NHC(O)N(R²⁶)—, —SO₂N(R²⁶)—, —N(R²⁶)SO₂—, —Si(R²⁶)₂—, —OSi(R²⁶)₂—, —Si(CH₃)₂—Ph—Si(CH₃)₂— and a bivalent organopolysiloxane residue (hereinafter referred to as “bond B¹”).

In the above formulae, R²⁶ is a hydrogen atom, a C₁₋₆ alkyl group or a phenyl group, and Ph is a phenylene group. The number of carbon atoms in the alkyl group as R²⁶ is, in view of easiness of production of the Compound (A1), preferably 1 to 6, more preferably 1 to 3, further preferably 1 to 2.

As the bivalent organopolysiloxane residue, the following groups may, for example, be mentioned. In the following formulae, R²⁷ is a hydrogen atom, an alkyl group, an alkoxy group or a phenyl group. The number of carbon atoms in the alkyl group or the alkoxy group as R²⁷ is preferably 1 to 10, more preferably 1. The plurality of R²⁷ may be the same or different from each other.

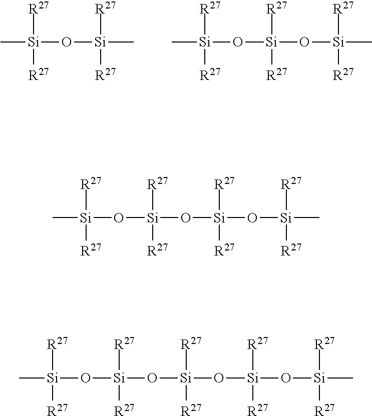

The bond B¹ is, in view of easiness of production of the Compound (A1), preferably at least one bond selected from the group consisting of —C(O)NR²⁶—, —N(R²⁶)C(O)—, —C(O)—, and —NR²⁶—, more preferably —C(O)NR²⁶—, —N(R²⁶)C(O)— or —C(O)—, whereby the obtainable surface layer will be more excellent in light resistance and chemical resistance.

In bivalent L¹, the atoms bonded to R¹ and R¹¹ are each independently N, O, S, Si, or a carbon atom having a hydroxy group or an oxo group (═O). That is, the atoms adjacent to R¹ and R¹¹ are respectively elements constituting the bond B¹. Specific examples of the bivalent L¹ include 1 or more of the bonds B¹ (for example *-B¹-**, *-B¹-R²⁸-B¹-**). R²⁸ is a single bond or a bivalent organic group, * is a binding site on the R¹ side, and ** is a binding site on the R¹¹ side.

In trivalent or higher valent L¹, the atoms bonded to R¹ and R¹¹ are each independently N, O, S, Si, a carbon atom constituting the branch point, or a carbon atom having a hydroxy group or an oxo group (═O). That is, the atoms adjacent to R¹ and R¹¹ are respectively elements constituting the bond B¹ or the branch point P¹. Specific examples of the trivalent or higher valent L¹ include 1 or more of the branch points P¹ (for example {(*-)ⱼP¹(-**)ₓ₁}, {(*-)ⱼP¹-R²⁸-P¹(-**)ₓ₁}), a combination of 1 or more of the branch points P¹ and 1 or more of the bonds B¹ (for example {*-B¹-R²⁸-P¹(-**)ₓ}, {*-B¹-R²⁸-P¹(-R²⁸-B¹-**)ₓ₁}). R²⁸ is a single bond or a bivalent organic group, * is a binding site on the R¹ side, and ** is a binding site on the R¹¹ side.

The bivalent organic group as R²⁸ may, for example, be a hydrocarbon group such as a bivalent aliphatic hydrocarbon group (e.g. an alkylene group or a cycloalkylene group), a bivalent aromatic hydrocarbon group (e.g. a phenylene group), and may have the bond B¹ between carbon atoms in the hydrocarbon group. The number of carbon atoms in the bivalent organic group is preferably 1 to 10, more preferably 1 to 6, further preferably 1 to 4.

The above L¹ is, in view of easiness of production of the Compound (A1), preferably a group represented by any one of the following formulae (L1) to (L7).

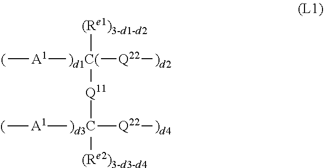

(-A¹-)_{d5}C(R^{e2})_{4-d5-d6}(-Q²²-)_{d6} (L2)

(-A²-)_{d7}N(-Q²³-)_{3-d7} (L3)

(-A³-)_{d8}Z¹(-Q²⁴-)_{d9} (L4)

(-A²-)_{d10}Si(R^{e3})_{4-d10-d11}(-Q²⁵-)_{d11} (L5)

-A¹-Q²⁶- (L6)

-A¹-CH(-Q²²-)-Si(R^{e3})_{3-d12}(-Q²⁵-)_{d12} (L7)

The group of each of the formulae (L1) to (L7) is linked to R¹ of the formula (A1) on the A¹, A² or A³ side, and is linked to R¹¹ on the Q²², Q²³, Q²⁴, Q²⁵ or Q²⁶ side.

A¹ is a single bond, -B³-, -B³-R³⁰-, or, -B³-R³⁰-B²-, wherein R³⁰ is an alkylene group or a group having —C(O)NR^{e6}—, —C(O)—, —CO(O)—, —NR^{e6}— or —O— between carbon atoms of an alkylene group having 2 or more carbon atoms, B² is —C(O)NR^{e6}—, —C(O)—, —NR^{e6}— or —O—, and B³ is —C(O)NR^{e6}—, —C(O)—, or —NR^{e6}—,
A² is a single bond or -B³-R³⁰-,
A³ is A¹ in a case where the atom in Z¹ to which A³ is bonded is a carbon atom, and is A² in a case where the atom in Z¹ to which A³ is bonded is a nitrogen atom,
Q¹¹ is a single bond, —O—, an alkylene group, or a group having —C(O)NR^{e6}—, —C(O)—, —NR^{e6}— or —O— between carbon atoms in an alkylene group having 2 or more carbon atoms,
Q²² is a single bond, -B³-, -R³⁰-B³- or -B²-R³⁰-B³-,
Q²³ is a single bond or -R³⁰-B³-,
Q²⁴ is Q²² in a case where the atom in Z¹ to which Q²⁴ is bonded is a carbon atom, and is Q²³ in a case where the atom in Z¹ to which Q²⁴ is bonded is a nitrogen atom,
Q²⁵ is a single bond or -R³⁰-B³-,
Q²⁶ is a single bond or -R³⁰-B³-,
Z¹ is a (d8+d9)-valent group having a cyclic structure, having a carbon atom or a nitrogen atom to which A³ is directly bonded and having a carbon atom or a nitrogen atom to which Q²⁴ is directly bonded,
R^{e1} is a hydrogen atom or a hydrocarbon group (e.g. an alkyl group or an aromatic hydrocarbon group such as a phenyl group),
R^{e2} is a hydrogen atom, a hydroxy group, a hydrocarbon group (e.g. an alkyl group or an aromatic hydrocarbon group such as a phenyl group) or an acyloxy group,
R^{e3} is a hydrocarbon group (e.g. an alkyl group or an aromatic hydrocarbon group such as a phenyl group),
R^{e6} is a hydrogen atom, a C₁₋₆ alkyl group or a phenyl group,
d1 is an integer of 0 to 3, d2 is an integer of 0 to 3, and d1+d2 is an integer of 1 to 3,
d3 is an integer of 0 to 3, d4 is an integer of 0 to 3, and d3+d4 is an integer of 1 to 3,
d1+d3 is an integer of 1 to 5,
d2+d4 is an integer of 1 to 5,
d5 is an integer of 1 to 3, d6 is an integer of 1 to 3, and d5+d6 is an integer of 2 to 4,
d7 is 1 or 2,
d8 is an integer of 1 or more,
d9 is an integer of 1 or more,
d10 is an integer of 1 to 3, d11 is an integer of 1 to 3, and d10+d11 is an integer of 2 to 4, and
d12 is an integer of 1 to 3.

The directions of B² and B³ are not limited. When there is a plurality of A¹, the plurality of A¹ may be the same or different from each other. The same applies to A², A³, Q²², Q²³, Q²⁴, Q²⁵, R^{e1}, R^{e2}, and R^{e3}.

Further, d1+d3, d5, d7, d8, d10 are j, and d2+d4, d6, 3-d7, d9, d11, and 1+d12 are x1.

The number of carbon atoms in the alkylene group as R³⁰ is preferably 1 to 10, more preferably 1 to 6, further preferably 1 to 4, in view of easiness of production of the Compound (A1), and whereby the obtainable surface layer will be more excellent in abrasion resistance, light resistance and chemical resistance. In a case where the alkylene group has a specific bond between carbon atoms, the lower limit of the number of carbon atoms in such an alkylene group is 2.

The cyclic structure in Z¹ may be the above described cyclic structure, and its preferred embodiment is also the same.

The number of carbon atoms in the alkyl group as R^{e1}, R^{e2} or R^{e3} is, in view of easiness of production of the Compound (A1), preferably 1 to 6, more preferably 1 to 3, further preferably 1 to 2.

The number of carbon atoms in the alkyl group moiety of the acyloxy group as R^{e2} is, in view of easiness of production of the Compound (A1), preferably 1 to 6, more preferably 1 to 3, further preferably 1 to 2.

d9 is preferably 2 to 6, more preferably 2 to 4, further preferably 2 or 3, in view of easiness of production of the Compound (A1), and whereby the obtainable surface layer will be more excellent in abrasion resistance and fingerprint stain removability.

As other embodiments of L¹, groups represented by the following formulae (L11) to (L17) may, for example, be mentioned.

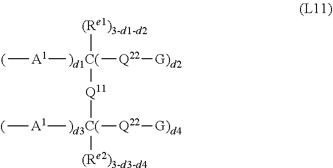

(-A¹-)_{d5}C(R^{e2})_{4-d5-d6}(-Q²²-G)_{d6} (L12)

(-A²-)_{d7}N(-Q²³-G)_{3-d7} (L13)

(-A³-)_{d8}Z¹(-Q²⁴-G)_{d9} (L14)

(-A²-)_{d10}Si(R^{e3})_{4-d10-d11}(-Q²⁵-G)_{d11} (L15)

-A¹-Q²⁶-G (L16)

-A¹-CH(-Q²²-G)-Si(R^{e3})_{3-d12}(-Q²⁵-G)_{d12} (L17)

The group of each of the formulae (L11) to (L17) is linked to R¹ of the formula (A1) on the A¹, A² or A³ side, and is linked to R¹¹ on the Q²², Q²³, Q²⁴, Q²⁵ or Q²⁶ side. G is the following group (G21), and 2 or more G which L¹ has may be the same or different from each other. Symbols other than G are the same as the symbols in the formulae (L1) to (L7).

-Si(R⁵¹)₃₋ₖ(-Q³-)ₖ (G21)

The above group of the formula (G21) is linked to Q²², Q²³, Q²⁴, Q²⁵ or Q²⁶ on the Si side, and is linked to R¹¹ on the Q³ side. R⁵¹ is an alkyl group. Q³ is a single bond, or -R⁵²-B³-, R⁵² is an alkylene group, a group having —C(O)NR³²—, —C(O)—, —NR³²— or —O— between carbon atoms in an alkylene group having 2 or more carbon atoms, or —(OSi(R²²)₂)ₚ₁₁—O—, and 2 or more Q³ may be the same or different from each other. k is 2 or 3. R³² is a hydrogen atom, a C₁₋₆ alkyl group or a phenyl group. R²² is an alkyl group, a phenyl group or an alkoxy group, and the two R²² may be the same or different from each other. p11 is an integer of 0 to 5, and when p11 is 2 or more, the 2 or more (OSi(R²²)₂) may be the same or different from each other.

In a case where Q³ is -R⁵²-B³-, the number of carbon atoms in the alkylene group as R⁵² is preferably 1 to 10, more preferably 1 to 6, further preferably 1 to 4, in view of easiness of production of the Compound (A1), and whereby the obtainable surface layer will be more excellent abrasion resistance, light resistance and chemical resistance. In a case where the alkylene group has a specific bond between carbon atoms, the lower limit of the number of carbon atoms in such an alkylene group is 2.

The number of carbon atoms in the alkyl group as R⁵¹ is, in view of easiness of production of the Compound (A1), preferably 1 to 6, more preferably 1 to 3, further preferably 1 to 2.

The number of carbon atoms in the alkyl group as R²² is, in view of easiness of production of the Compound (A1), preferably 1 to 6, more preferably 1 to 3, further preferably 1 to 2.

The number of carbon atoms in the alkoxy group as R²² is, in view of excellent storage stability of the Compound (A1), preferably 1 to 6, more preferably 1 to 3, further preferably 1 to 2.

p11 is preferably 0 or 1.

In the Compound (A1), the molecular weight of the group represented by L¹-(R¹¹-T¹¹)ₓ₁ is 600 or more. The molecular weight of the group represented by L¹-(R¹¹-T¹¹)ₓ₁ is preferably 610 or more, more preferably 615 or more, further preferably 620 or more. When the molecular weight of the group represented by L¹-(R¹¹-T¹¹)ₓ₁ is within the above range, the obtainable surface layer will have more improved abrasion resistance.

On the other hand, the molecular weight is preferably 2,000 or less, more preferably 1,500 or less, further preferably 1,000 or less, in view of more excellent antifouling property.

The ratio of the molecular weight of the fluoropolyether chain represented by [R^{f1}-(OR^{f11})_{y1}-O-R¹]ⱼ to the molecular weight of the group represented by L¹-(R¹¹-T¹¹)ₓ₁, is preferably 10% or more, more preferably 12% or more, further preferably 13% or more, whereby the obtainable surface layer will have more improved abrasion resistance.

The ratio is preferably 40% or less, more preferably 25% or less, in view of more excellent antifouling property.

As the Compound (A1), the following may, for example, be mentioned.

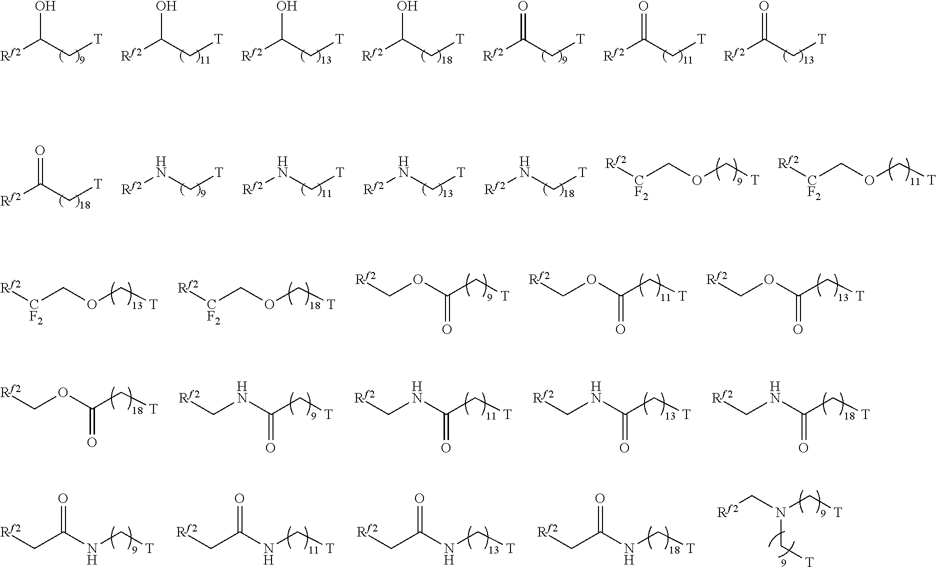

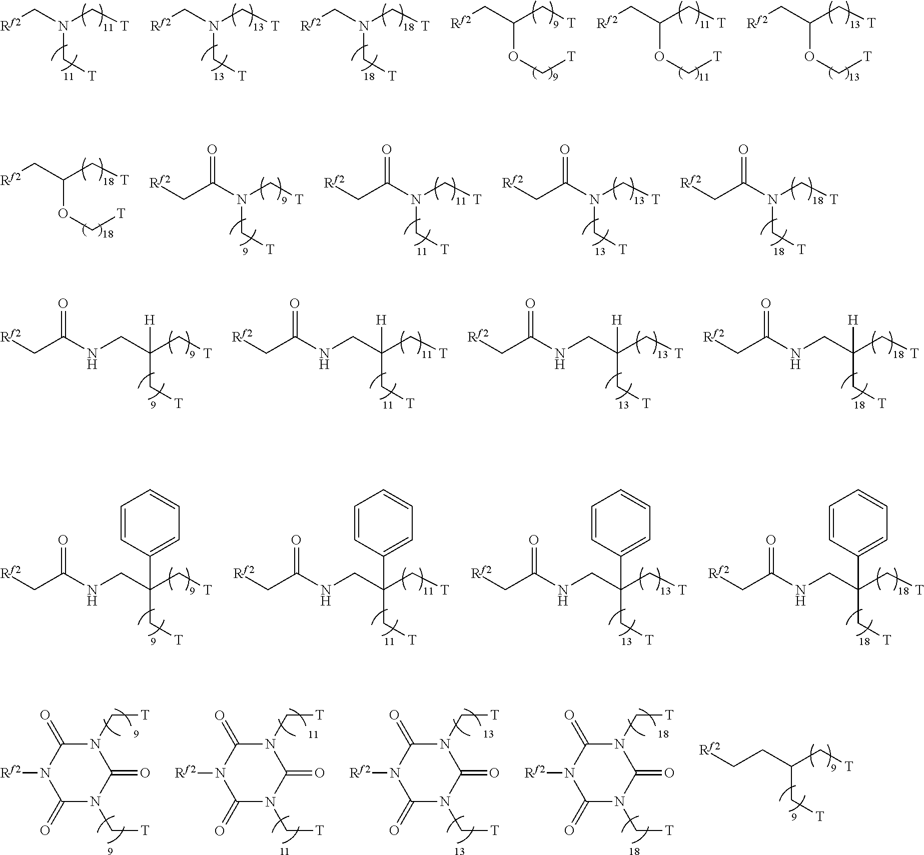

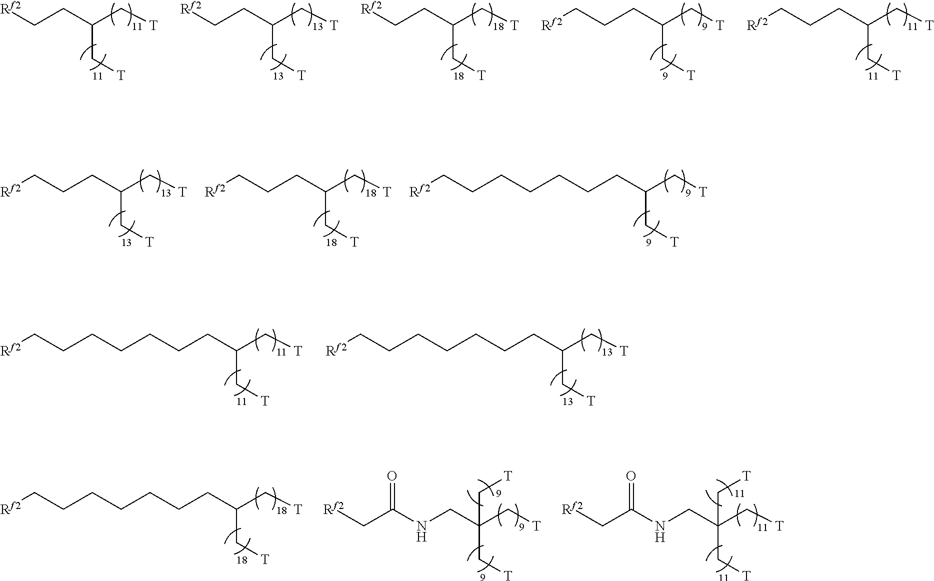

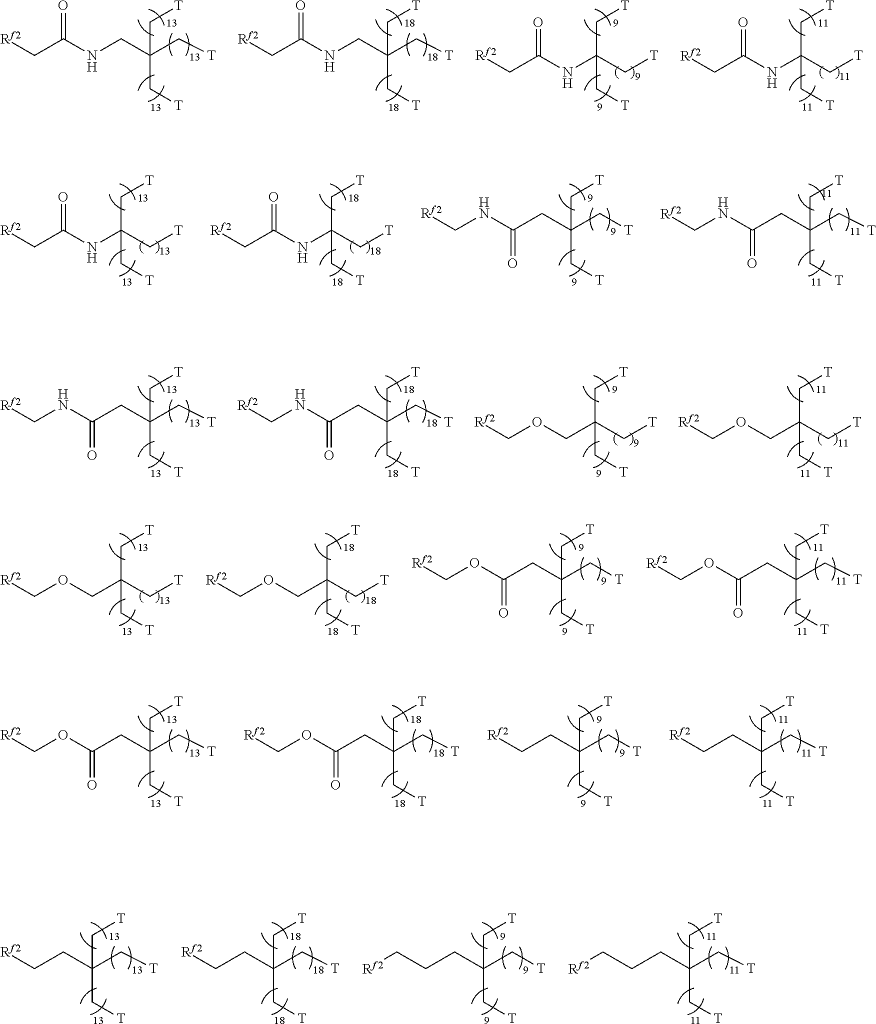

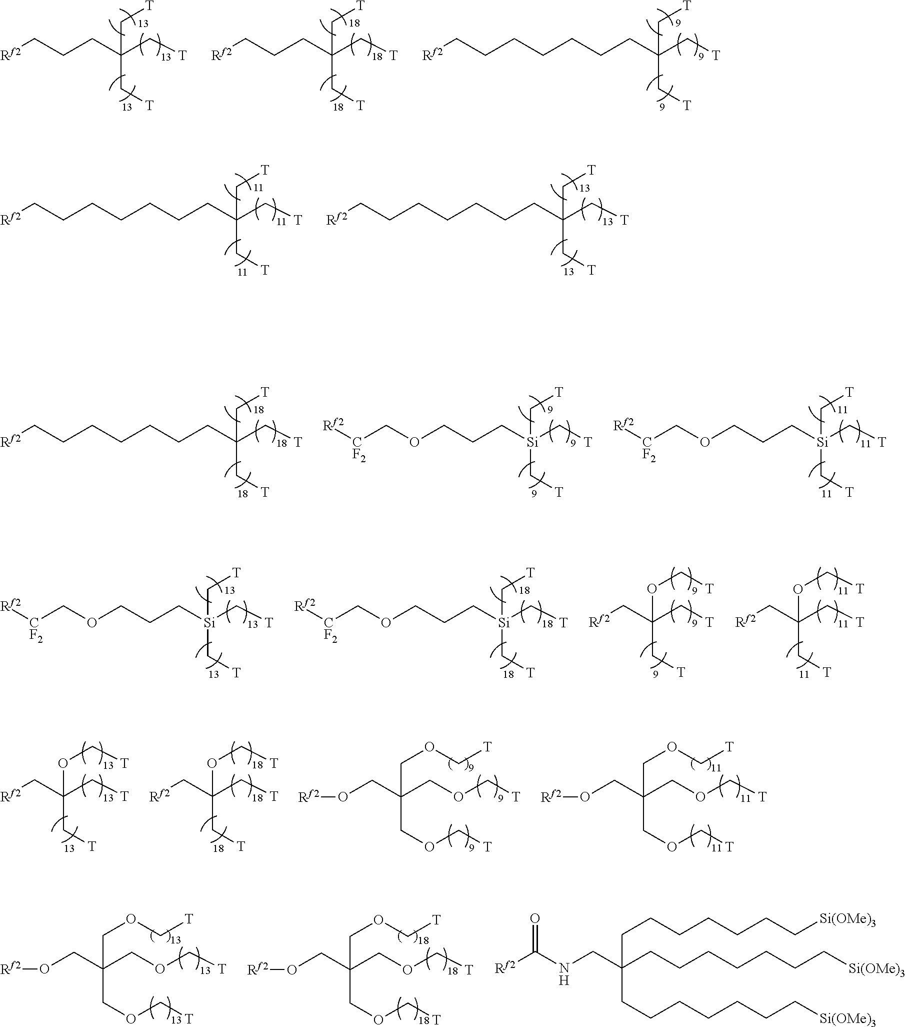

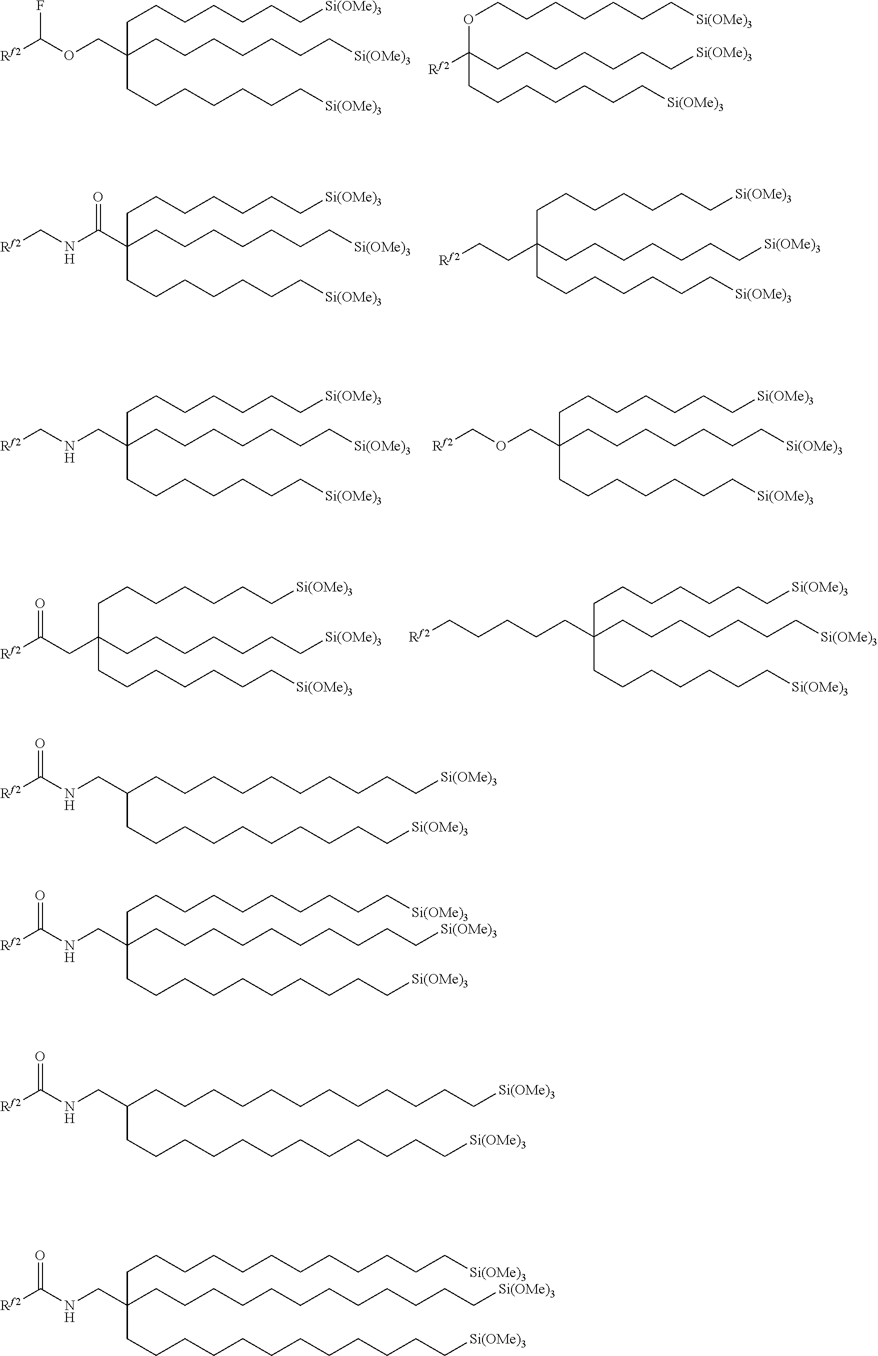

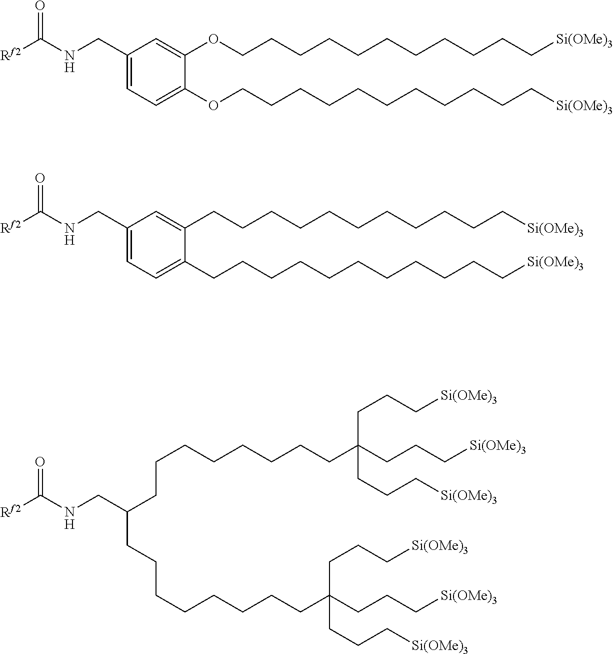

R^{f2} is each independently the same as [R^{f1}-(OR^{f11})_{y1}-O-R¹] or [R^{f1}-(OR^{f11})_{y1}-O-], T is the same as T¹¹, and Me represents a methyl group.

### Compound (A2)

The Compound (A2) has a structure represented by the following formula (A2).

(T³¹-R³¹)ₓ₃-L³-R³-(OR^{f12})_{y2}-O-R²-L²-(R²¹-T²¹)ₓ₂ (A2)

Symbols in the formula (A2) are as defined above.

R^{f12} and (OR^{f12})_{y2} are the same as the above R^{f11} and (OR^{f11})_{y1}, and their preferred embodiments are also the same.

R² and R³ are each independently the same as R¹, and their preferred embodiments are also the same.

R²¹ and R³¹ are the same as R¹¹, and their preferred embodiments are also the same. “Bonded to L¹” is read as “bonded to L²” in the case of R²¹, and is read as “bonded to L³” in the case of R³¹. “Bonded to T¹¹” is read as “bonded to T²¹” in the case of R²¹, and is read as “bonded to T³¹” in the case of R³¹. In a case where L² is a single bond, R²¹ is directly bonded to R². In a case where L³ is a single bond, R³¹ is directly bonded to R³.

T²¹ and T³¹ are each independently -SiR^{a21}_{z21}R^{a22}_{3-z21}, R^{a21}, R^{a22} and z21 are each independently the same as R^{a11}, R^{a12} and z11 constituting T¹¹, and their preferred embodiments are also the same.

x2 and x3 are each independently the same as x1, and their preferred embodiments are also the same.

L² and L³ are each independently the same as L¹ wherein j is 1.

For example in a case where L² and L³ are a single bond, the Compound (A2) is represented by the following formula (A2′).

T³¹-R³¹-R³-(OR^{f12})_{y2}-O-R²-R²¹-T²¹ (A2′)

Symbols in the formula (A2′) are as defined for the formula (A2).

In a case where L² or L³ is a trivalent or higher valent group, the trivalent or higher valent L² or L³ has at least one type of branch point (hereinafter referred to as “branch point P²”) selected from the group consisting of C, N, Si, a cyclic structure and a (1+x2)-valent or (1+x3)-valent organopolysiloxane residue.

In a case where the branch point P² is N, the branch point P² is represented, for example, by *-N(-**)₂. * is a binding site on the R² or R³ side, and ** is a binding site on the R²¹ or R³¹side.

In a case where the branch point P² is C, the branch point P² is represented, for example, by *-C(-**)₃, or *-CR²⁹(-**)₂. * is a binding site on the R² or R³ side, * is a binding site on the R²¹ or R³¹ side, and R²⁹ is a monovalent group. R²⁹ may, for example, be a hydrogen atom, a hydroxy group, an alkyl group, or an alkoxy group.

In a case where the branch point P² is Si, the branch point P² is represented, for example, by *-Si(-**)₃, or *-SiR²⁹(-**)₂.

* is a binding site on the R² or R³ side, ** is a binding site on the R²¹ or R³¹side, and R²⁹ is a monovalent group. R²⁹ may, for example, be a hydrogen atom, a hydroxy group, an alkyl group, or an alkoxy group.

The cyclic structure and the organopolysiloxane residue constituting the branch point P² are the same as for the branch point P¹, and their preferred embodiments are also the same.

The bivalent or higher valent L² and L³ may each independently have the bond B¹. The embodiment of the bond B¹ is as defined above, and its preferred embodiment is also the same.

In the bivalent L² or L³, the atoms bonded to R² and R²¹, or R³ and R³¹, are each independently N, O, S, Si, or a carbon atom having a hydroxy group or an oxo group (═O). That is, the atoms adjacent to R² and R²¹, or R³ and R³¹, are respectively elements constituting the bond B¹. Specific examples of the bivalent L² or L³ include 1 or more of the bonds B¹ (for example *-B¹-**, *-B¹-R²⁸-B¹-**). R²⁸ is a single bond or a bivalent organic group, * is a binding site on the R² or R³ side, and ** is a binding site on the R²¹ or R³¹ side.

In the trivalent or higher L² or L³, the atoms bonded to R² and R²¹, or R³ and R³¹ are each independently N, O, S, Si, a carbon atom constituting the branch point, or a carbon atom having a hydroxy group or an oxo group (═O). That is, the atoms adjacent to R² and R²¹, or R³ and R³¹, are respectively elements constituting the bond B¹ or the branch point P². Specific examples of the trivalent or higher valent L² or L³ include 1 or more of the branch points P² (for example {*-P²(-**)ₓ}, {*-P²-R²⁸-P²-**ₓ}), and a combination of 1 or more of the branch points P² and 1 or more of the bonds B¹ (for example {*-B¹-R²⁸-P²(-**)ₓ}, {*-B¹-R²⁸-P²(-R²⁸-B¹-**)ₓ}). x is x2 in the case of L², and is x3 in the case of L³. R²⁸ is a single bond or a bivalent organic group, * is a binding site on the R² or R³ side, and ** is a binding site on the R²¹ or R³¹ side.

The embodiment of the above R²⁸ is as described above, and its preferred embodiment is also the same.

L² or L³ are, in view of easiness of production of the Compound (A2), each independently preferably any one of groups represented by the following formulae (L21) to (L27).

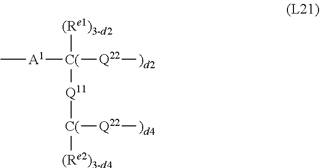

-A¹-C(R^{e2})_{4-d6}(-Q²²-)_{d6} (L22)

-A²-N(-Q²³-)₂ (L23)

-A³-Z¹(-Q²⁴-)_{d9} (L24)

-A²-Si(R^{e3})_{4-d11}(-Q²⁵-)_{d11} (L25)

-A¹-Q²⁶- (L26)

-A¹-CH(-Q²²-)-Si(R^{e3})_{3-d12}(-Q²⁵-)_{d12} (L27)

The group of each of the formulae (L21) to (L27) is linked to R² or R³ on the A¹, A² or A³ side, and is linked to R²¹ or R³¹ on the Q²², Q²³, Q²⁴, Q²⁵ or Q²⁶ side.

A¹, A², A³, Q¹¹, Q²², Q²³, Q²⁴, Q²⁵, Q²⁶, R^{e1}, R^{e2} and R^{e3} are as defined for L¹, and their preferred embodiments are also the same.

Z¹ is a (1+d9)-valent group having a cyclic structure, having a carbon atom or a nitrogen atom to which A³ is directly bonded and having a carbon atom or a nitrogen atom to which Q²⁴ is directly bonded,
d2 is an integer of 0 to 3, d4 is an integer of 0 to 3, and d2+d4 is an integer of 1 to 5,
d6 is an integer of 1 to 3,
d9 is an integer of 1 or more,
d11 is an integer of 1 to 3, and
d12 is an integer of 1 to 3.

d2+d4, d6, d9, d11, and 1+d12 are x2 or x3.

d9 is preferably 2 to 6, more preferably 2 to 4, further preferably 2 or 3, in view of easiness of production of the Compound (A2) and whereby the obtainable surface layer will be more excellent in abrasion resistance and fingerprint stain removability.

As other embodiments of L² and L³, groups represented by the following formulae (L31) to (L37) may be mentioned.

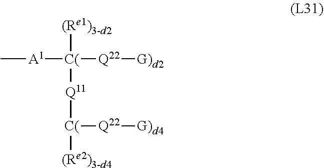

-A¹-C(R^{e2})_{4-d6}(-Q²²-G)_{d6} (L32)

-A²-N(-Q²³-G)₂ (L33)

-A³-Z¹(-Q²⁴-G)_{d9} (L34)

-A²-Si(R^{e3})_{4-d11}(-Q²⁵-G)_{d11} (L35)

-A¹-Q²⁶-G (L36)

-A¹-CH(-Q²²-G)-Si(R^{e3})_{3-d12}(-Q²⁵-G)_{d12} (L37)

The group of each of the formulae (L31) to (L37) is bonded to R² or R³ on the A¹, A² or A³ side, and is bonded to R²¹ or R³¹ on the Q²², Q²³, Q²⁴, Q²⁵ or Q²⁶ side. G is the above group (G21), and its preferred embodiment is also the same. Symbols other than G are the same as the symbols in the formulae (L21) to (L27), and their preferred embodiments are also the same.

In the Compound (A2), the molecular weight of at least one of the group represented by L²-(R²¹-T²¹)ₓ₂ and the group represented by (T³¹-R³¹)ₓ₃-L³ is 600 or more.

The above molecular weight is preferably 610 or more, more preferably 615 or more, further preferably 620 or more, whereby the obtainable surface layer will have more improved abrasion resistance.

On the other hand, the above molecular weight is preferably 2,000 or less, more preferably 1,500 or less, further preferably 1,000 or less, in view of more excellent antifouling property.

It is preferred that both the molecular weight of the group represented by L²-(R²¹-T²¹)ₓ₂ and the molecular weight of the group represented by (T³¹-R³¹)ₓ₃-L³ are within the above range.

The ratio of the molecular weight of the group represented by R³-(OR^{f12})_{y2}-O-R² to the sum of the molecular weight of the group represented by L²-(R²¹-T²¹)ₓ₂ and the molecular weight of the group represented by (T³¹-R³¹)ₓ₃-L³, is preferably 10% or more, more preferably 12% or more, further preferably 13% or more, whereby the obtainable surface layer will have more improved abrasion resistance.

The above ratio is, in view of more excellent antifouling property, preferably 40% or less, more preferably 25% or less.

As the Compound (A2), the following may, for example, be mentioned.

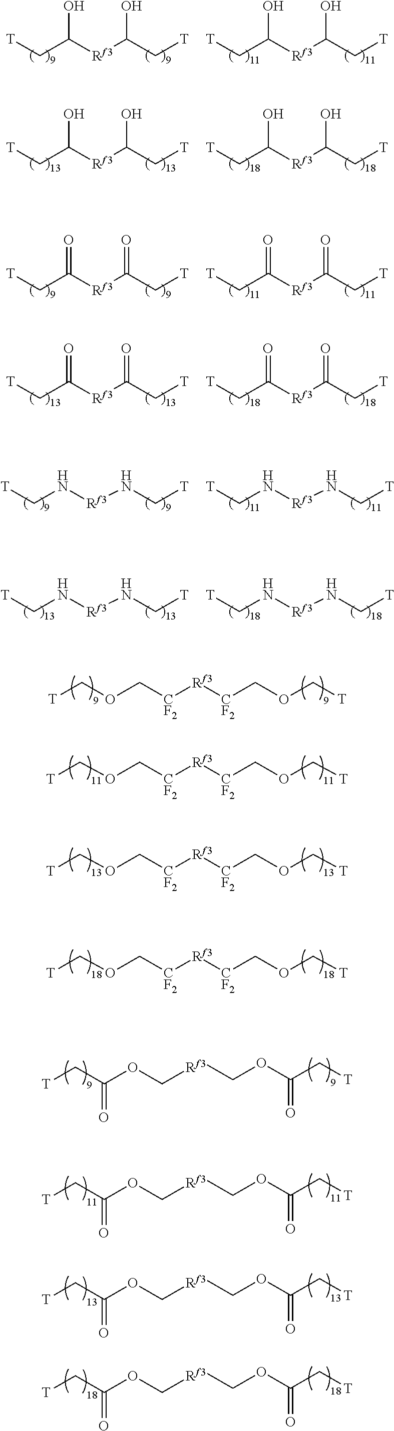

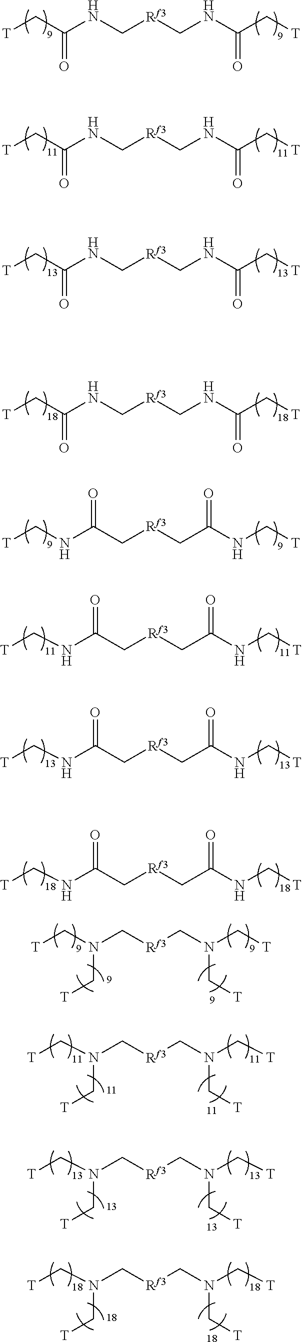

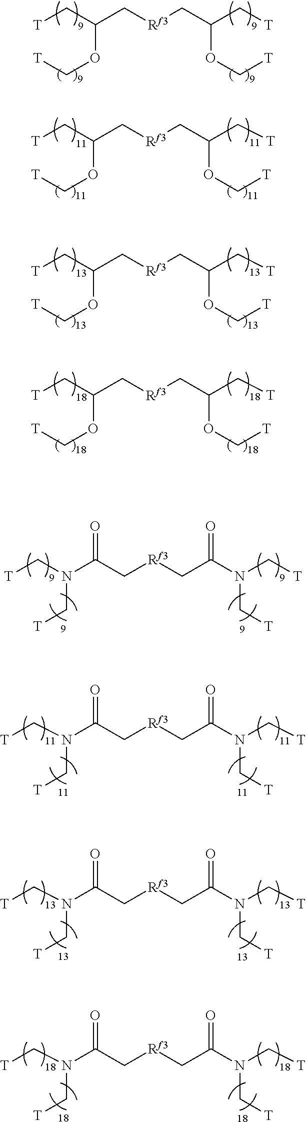

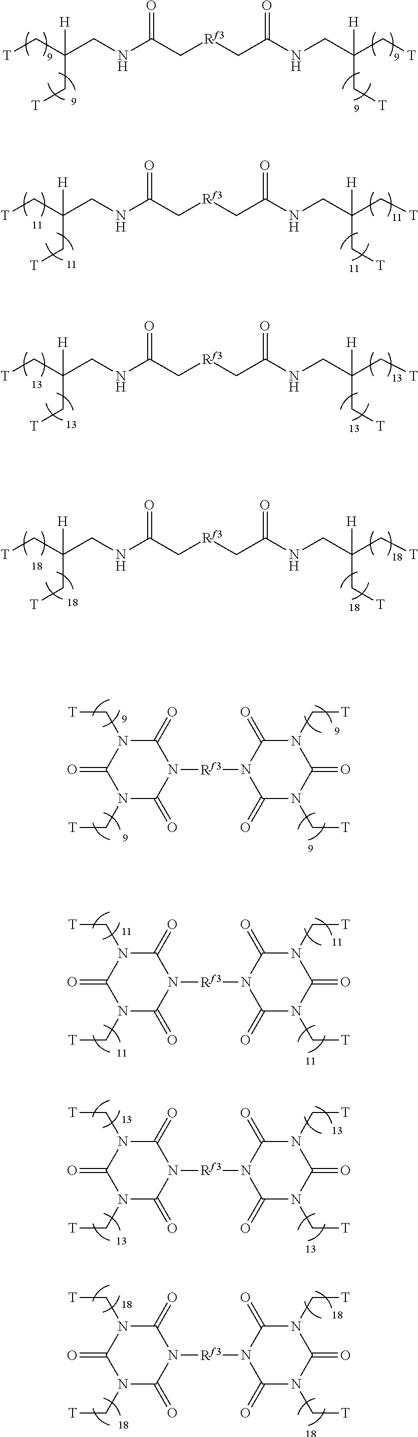

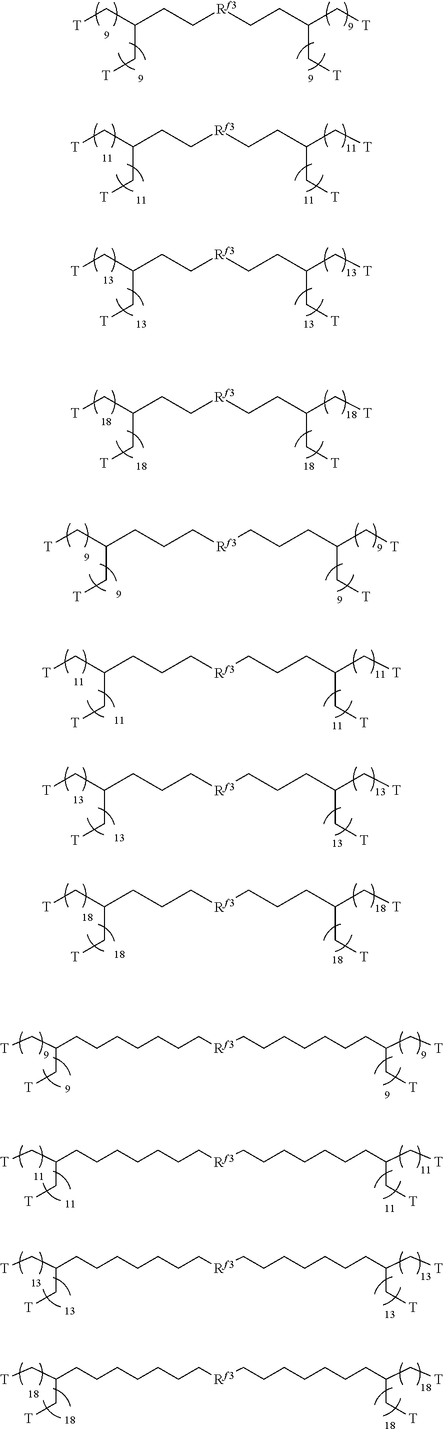

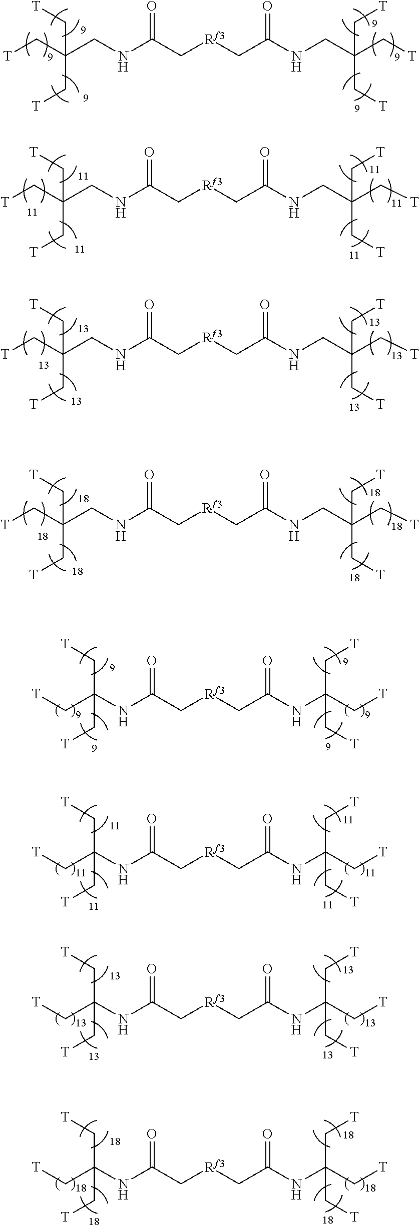

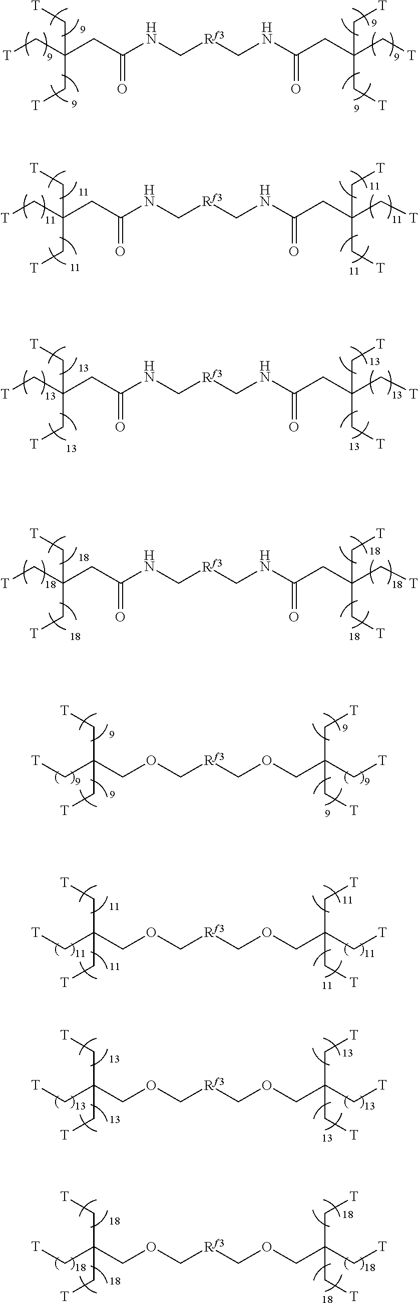

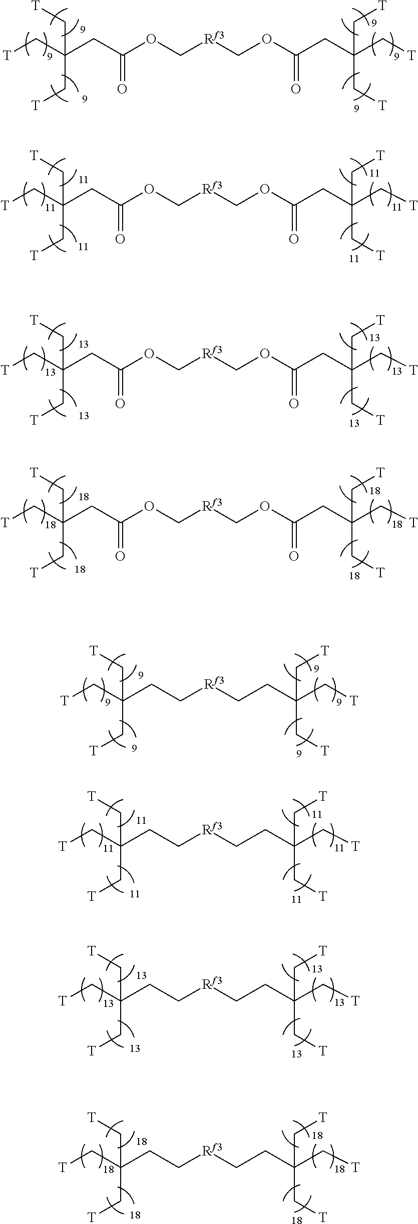

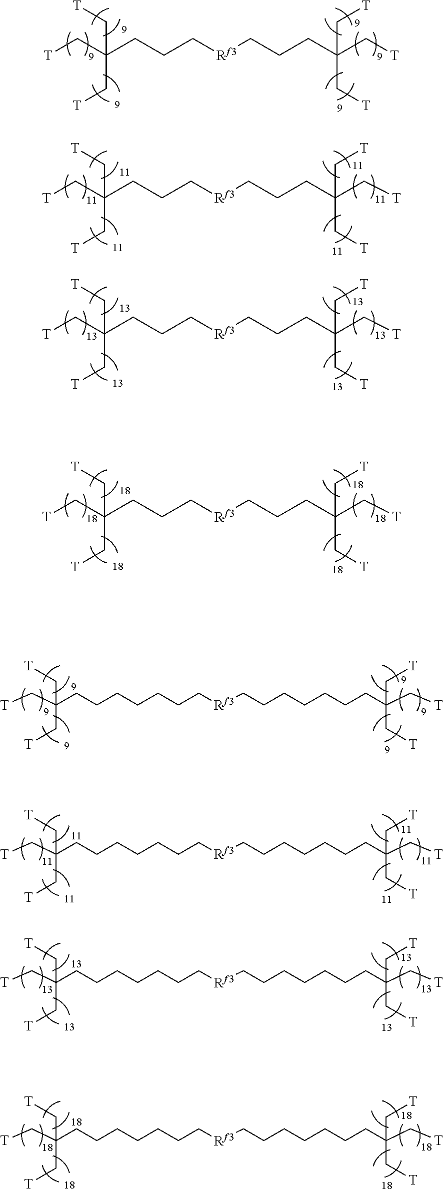

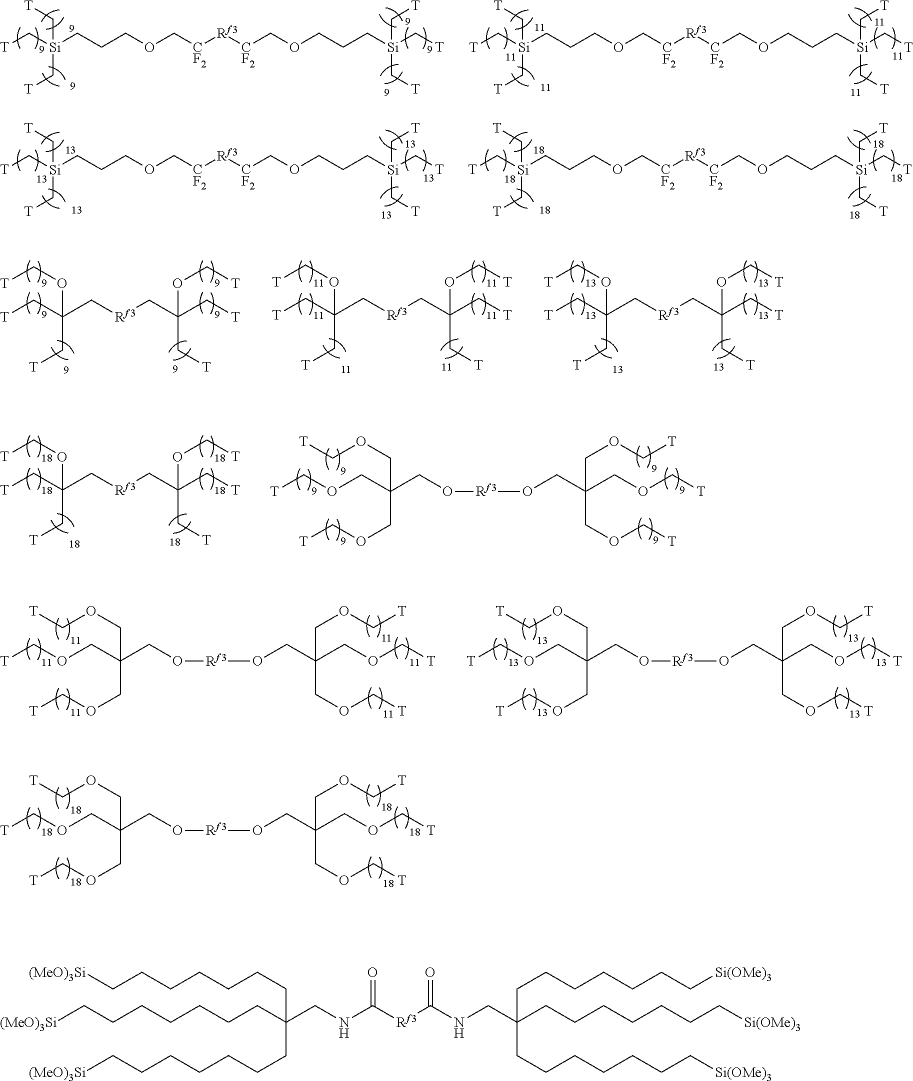

R^{f3} is each independently the same as [R³-(OR^{f12})_{y2}-O-R²] or [(OR^{f12})_{y2}-O], and T is the same as T²¹ or T³¹.

### Compound (A3)

The Compound (A3) has a structure represented by the following formula (A3).

Q¹[-(OR^{f13})_{y3}-O-R⁴-L⁴-(R⁴¹-T⁴¹)ₓ₄]ᵣ₁ (A3)

Symbols in the formula (A3) are as defined above.

R^{f13} and (OR^{f13})_{y3} are the same as R^{f11} and (OR^{f11})_{y1}, and their preferred embodiments are also the same.

R⁴ is the same as R¹, and its preferred embodiment is also the same.

R⁴¹ is the same as R¹¹, and its preferred embodiment is also the same. “Bonded to L¹” is read as “bonded to L⁴”. “Bonded to T¹¹” is read as “bonded to T⁴¹”. In a case where L⁴ is a single bond, R⁴¹ is directly bonded to R⁴.

T⁴¹ is -SiR^{a41}_{z41}R^{a42}_{3-z41}, R^{a41}, R^{a42} and z41 are each independently the same as R^{a11}, R^{a12} and z11 constituting T¹¹, and their preferred embodiments are also the same.

Q¹ is a r1-valent group having a branch point, and r1 is 3 or 4.

The branch point constituting Q¹ (hereinafter referred to as “branch point P³”) may, for example, be N, C, Si or a cyclic structure. Q¹ may have one of such a branch point P³, or may have 2 or more of such branch points P³.

In a case where the branch point P³ is N, the branch point P³ is represented for example by N(-*)₃, or NR²⁹(-*)₂.

In a case where the branch point P³ is C, the branch point P³ may, for example, be C(-*)₄, CR²⁹(-*)₃, or C(R²⁹)₂(-*)₂.

In a case where the branch point P³ is Si, the branch point P³ may, for example, be Si(-*)₄, SiR²⁹(-*)₃, or Si(R²⁹)₂(-*)₂.

* is a binding site on the OR^{f13} side, and R²⁹ is a monovalent group. R²⁹ may, for example, be a hydrogen atom, a fluorine atom, a hydroxy group, an alkyl group, a fluoroalkyl group, or a fluoropolyether chain having no R⁴¹-T⁴¹.

The cyclic structure constituting the branch point P³ may, for example, be the same cyclic structure constituting the branch point P¹, and the cyclic structure may further have, as a substituent, in addition to the above substituent, at least one group selected from the group consisting of a fluorine atom, a fluoroalkyl group and a fluoropolyether chain having no R⁴¹-T⁴¹.

As Q¹, in view of easiness of production of the Compound (A3), preferred are groups represented by the following formulae (Q1) to (Q6).

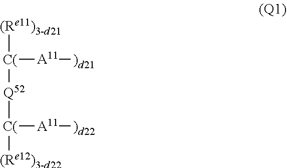

C(-A¹¹-)_{d23}(R^{e12})_{4-d23} (Q2)

N(-A¹²-)₃ (Q3)

Z¹(-A¹³-)_{d24} (Q4)

Si(-A¹²-)_{d25}(R^{e13})_{4-d25} (Q5)

CH(-A¹¹-)₂-Si(R^{e13})_{3-d26}(-A¹¹-)_{d26} (Q6)

In the formulae (Q1) to (Q6), A¹¹, A¹² or A¹³ is linked to (OR^{f13}).

A¹¹ is a single bond, -R⁴⁰-, or -B¹³-R⁴⁰-, R⁴⁰ is an alkylene group, a fluoroalkylene group or a group having —C(O)NR^{e16}—, —C(O)—, —CO(O)—, —NR^{e16}— or —O— between carbon atoms of an alkylene group or fluoroalkylene group having 2 or more carbon atoms, B¹³ is —C(O)NR^{e16}—, —C(O)—, —NR^{e16}— or —O—,
A¹² is a single bond or -R⁴⁰-,
A¹³ is A¹¹ in a case where the atom in Z¹ to which A¹³ is bonded is a carbon atom, and is A¹² in a case where the atom in Z¹ to which A¹³ is bonded is a nitrogen atom,
Z¹ is a r1-valent group having a cyclic structure having a carbon atom or nitrogen atom to which A¹³ is directly bonded,
Q⁵² is a single bond, —O—, an alkylene group, a fluoroalkylene group, or a group having —C(O)NR^{e16}—, —C(O)—, —NR^{e16}— or —O— between carbon atoms in an alkylene group or a fluoroalkylene group having 2 or more carbon atoms,
R^{e11} is a hydrogen atom, a fluorine atom, an alkyl group, a fluoroalkyl group, a fluoropolyether chain having no R⁴¹-T⁴¹, or a group having a repeating structure of -Q⁵²-C(R^{e11})_{3-d21}(-A¹¹-)_{d21} within a range where r1 is 3 to 4,
R^{e12} is a hydrogen atom, a fluorine atom, a hydroxy group, an alkyl group, a fluoroalkyl group, or a fluoropolyether chain having no R⁴¹-T⁴¹,
R^{e13} is an alkyl group or a fluoroalkyl group,
R^{e16} is a hydrogen atom, a C₁₋₆ alkyl group, a fluoroalkyl group or a phenyl group which may be substituted with fluorine,
d21 is an integer of 0 to 3, d22 is an integer of 0 to 3, and d21+d22 is an integer of 3 to 4,
d23 is 3 or 4,
d24 is 3 or 4,
d25 is 3 or 4, and
d26 is 1 or 2.

The direction of B¹³ is not limited. When there is a plurality of A¹¹, the plurality of A¹¹ may be the same or different from each other. The same applies to A¹², A¹³, R^{e11}, R^{e12} and R^{e13}.

The number of carbon atoms in the alkylene group or the fluoroalkylene group as R⁴⁰ is preferably 1 to 10, more preferably 1 to 6, further preferably 1 to 4, in view of easiness of production of the Compound (A3), and whereby the obtainable surface layer will be more excellent in abrasion resistance, light resistance and chemical resistance. In a case where the alkylene group has a specific bond between carbon atoms, the lower limit of the number of carbon atoms in such an alkylene group is 2.

The cyclic structure in Z¹ may, for example, be the cyclic structure constituting the branch point P3, and its preferred embodiment is also the same.

The number of carbon atoms in the alkylene group or the fluoroalkylene group as R^{e11}, R^{e12} or R^{e13} is, in view of easiness of production of the Compound (A3), preferably 1 to 6, more preferably 1 to 3, further preferably 1 to 2.

In the Compound (A3), the molecular weight of at least one of the groups represented by L⁴-(R⁴¹-T⁴¹)ₓ₄ is 600 or more.

The molecular weight is preferably 610 or more, more preferably 615 or more, further preferably 620 or more, whereby the obtainable surface layer will have more improved abrasion resistance.

On the other hand, the molecular weight is, in view of more excellent antifouling property, preferably 2,000 or less, more preferably 1,500 or less, further preferably 1,000 or less.

It is preferred that the molecular weights of all the groups represented by L⁴-(R⁴¹-T⁴¹)ₓ₄ are within the above range.

The ratio of the sum of the sum of the molecular weights of r1 pieces of groups represented by (OR^{f13})_{y3}-O-R⁴ and the molecular weight of the group represented by Q¹, to the sum of the molecular weights of r1 pieces of groups represented by L⁴-(R⁴¹-T⁴¹)ₓ₄, is preferably 10% or more, more preferably 12% or more, further preferably 13% or more, whereby the obtainable surface layer will have more improved abrasion resistance.

The above ratio is, in view of more excellent antifouling property, preferably 40% or less, more preferably 25% or less.

As the Compound (A3), the following may, for example, be mentioned.

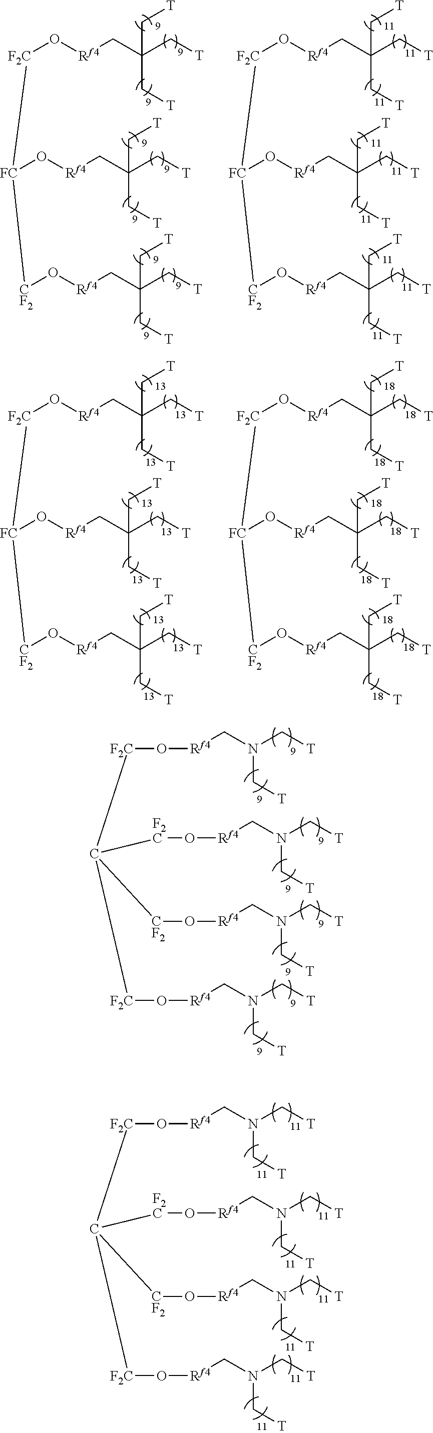

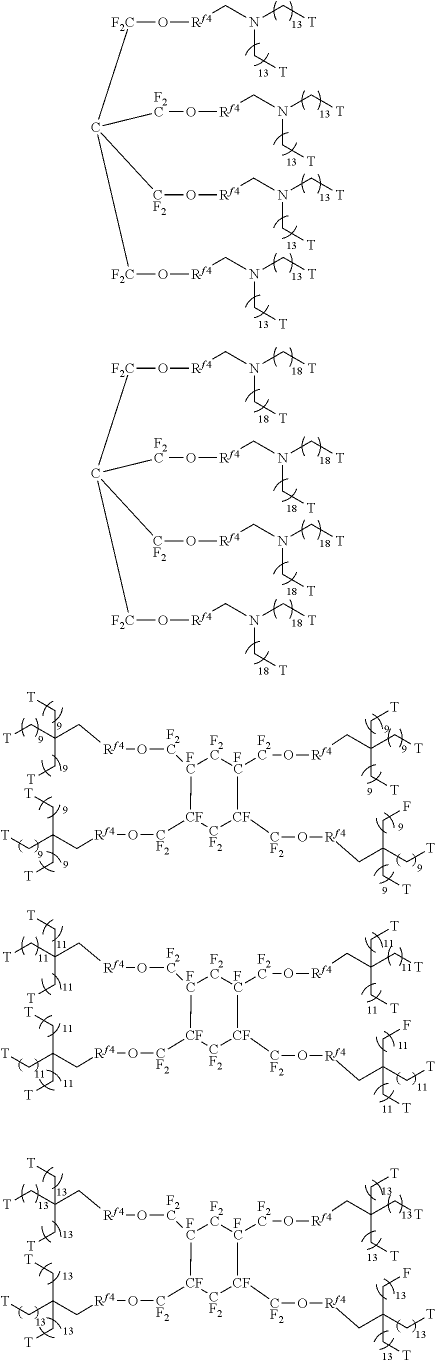

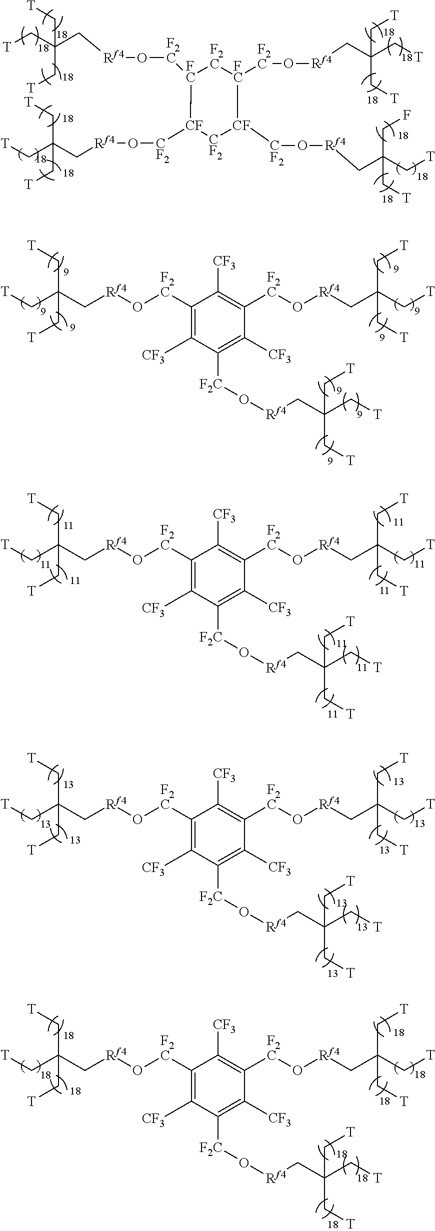

In the above compounds, {-O-R^{f4}-} is each independently the same as [-(OR^{f13})_{y3}-O-R⁴-]ᵣ₁, or [-(OR^{f13})_{y3}-O-]ᵣ₁, and T is the same as T⁴¹.

The present treatment agent may contain a single type of the present compound or may contain 2 or more types of the present compounds.

The content of the present compound is, to the total mass of the present treatment agent, preferably 0.001 to 40 mass %, more preferably 0.01 to 20 mass %, further preferably 0.01 to 10 mass %, particularly preferably 0.01 to 5 mass %.

### Method for Producing the Present Compound

The method for producing the present compound is not particularly limited and in view of e.g. easiness of production, preferred is a method of subjecting any one of the following Compound (B¹), the Compound (B2) and the Compound (B3), and the following Compound (C), to hydrosilylation reaction.

The Compound (B¹), the Compound (B2) and the Compound (B3) are respectively compounds represented by the following formula (B¹), the following formula (B2) and the following formula (B3).

[R^{f1}-(OR^{f11})_{y1}-O-R¹]ⱼ-L¹-(R¹¹-CH═CH₂)ₓ₁ (B¹)

(CH₂═CH-R³¹)ₓ₃-L³-R³-(OR^{f12})_{y2}-O-R²-L²-(R²¹-CH═CH₂)ₓ₂ (B2)

Q¹[-(OR^{f13})_{y3}-O-R⁴-L⁴-(R⁴¹-CH═CH₂)ₓ₄]ᵣ₁ (B3)

Symbols in the formulae are as defined above, and their preferred embodiments are also the same.

The Compound (C) is a compound represented by the following formula (C).

HSiR^{a1}_{z1}R^{a2}_{3-z1} (C)

In the formula, R^{a1}, R^{a2} and Z1 are each independently the same as R^{a11}, R^{a12} and z11 constituting T¹¹, and their preferred embodiments are also the same.

The Compounds (B1) to (B3) may be synthesized in accordance with a known synthesis method.

More specifically, a method of introducing the following Compound (E) to precursors of the Compounds (B1) to (B3) (for example the following Compounds (D1) to (D3)) may be mentioned.

[R^{f1}-(OR^{f11})_{y1}-O-R¹]ⱼ-L¹-(E¹)ₓ₁ (D1)

(E¹)ₓ₃-L³-R³-(OR^{f12})_{y2}-O-R²-L²-(E¹)ₓ₂ (D2)

Q¹[-(OR^{f13})_{y3}-O-R⁴-L⁴-(E¹)ₓ₄]ᵣ₁ (D3)

E²-R^{g2}-CH═CH₂ (E)

In the formulae,
E¹ is —OH, —OR, —C(O)—X, —I, —NH₂ or —CH═CH₂,
X is a halogen atom, an alkoxy group, a hydroxy group or an amino group,
R is an alkyl group,
E² is a substituent capable of addition reaction, selected from —OH, —OR, —C(O)—X, —I, —NH₂ and —CH═CH₂, depending upon E¹, and
R^{g2} is selected from R¹¹, R²¹, R³¹ and R⁴¹, depending upon the Compound (B1) to (B3) to be synthesized.

Other symbols are as defined above.

The method for synthesizing the Compounds (D1) to (D3), and the addition reaction of the compound corresponding to the Compound (E), are in accordance with the method described in WO2009/008380, the method described in WO2013/121984, the method described in WO2013/121986, the method described in WO2015/087902, the method described in Patent Document 1, the method described in WO2017/038832, the method described in WO2018/143433, the method described in JP-A-2017-104731, the method described in WO2021/060537, or the method described in WO2021/054417.

### Non-Fluorinated Organic Solvent

The present treatment agent contains an organic solvent containing no fluorine atom (non-fluorinated organic solvent).

The non-fluorinated organic solvent means an organic compound containing no fluorine atom, which is liquid at 25° C. under atmospheric pressure.

The non-fluorinated organic solvent may, for example, be a hydrocarbon-based organic solvent, an alcohol-based organic solvent, a ketone-based organic solvent, an ether-based organic solvent, an ester-based organic solvent, an amide-based organic solvent, or a sulfoxide-based organic solvent.

The hydrocarbon-based solvent is a compound composed solely of hydrogen atoms and carbon atoms and may be any of an aromatic hydrocarbon, an aliphatic hydrocarbon and an unsaturated hydrocarbon.

The aromatic hydrocarbon may, for example, be benzene, toluene, xylene, aniline or nitrobenzene.

The aliphatic hydrocarbon may, for example, be n-hexane, n-heptane, n-octane or n-decane.

The unsaturated hydrocarbon may, for example, be cyclopentene, hexene, heptene or butene.

The hydrocarbon solvent may also be petroleum benzine, mineral spirit or the like.

The ketone-based solvent may, for example, be acetone, methyl ethyl ketone, methyl isobutyl ketone, 2-hexanone, cyclohexanone, methyl amino ketone, 2-heptanone, diisobutyl ketone or diacetone alcohol.

The alcohol-based solvent may, for example, be methanol, ethanol, propanol, isopropanol or butanol. A glycol-based solvent described later is not included in the alcohol-based solvent.

The ether-based solvent may, for example, be diethyl ether, diisopropyl ether, methyl t-butyl ether, dimethoxyethane, 1,4-dioxane, 1,3-dioxolane, tetrahydrofuran, cyclopentyl methyl ether, 4-methyltetrahydrofuran, 2-methyltetrahydrofuran, or a glycol-based solvent.

The glycol-based solvent may, for example, be a mono-or di-alkylene glycol mono-or di-alkyl ether, or a mono-or di-alkylene glycol mono-or di-alkyl ether acetate. The alkylene group is preferably an ethylene group or a propylene group. The alkyl group is preferably a C₁₋₄ alkyl group, more preferably a methyl group or an ethyl group. The glycol-based solvent may, for example, be more specifically ethylene glycol monomethyl ether, ethylene glycol monoethyl ether, propylene glycol monomethyl ether, propylene glycol monoethyl ether or propylene glycol monobutyl ether.

The ester-based solvent may, for example, be ethyl acetate, isopropyl acetate, butyl acetate, amyl acetate, methyl formate, methyl butyrate, butyl butyrate, methyl lactate, ethyl lactate, methyl 3-methoxypropionate, ethyl 3-methoxypropionate, methyl 2-hydroxyisobutyrate, ethyl 2-hydroxyisobutyrate, or an esterified compound of the glycol-based solvent and a carboxylic acid such as acetic acid.

The amide-based organic solvent may, for example, be N,N-dimethylformamide.

The sulfoxide-based organic solvent may, for example, be dimethyl sulfoxide.

The non-fluorinated organic solvent is, in view of more excellent solubility of the present compound and abrasion resistance, preferably at least one member selected from the group consisting of an alcohol-based organic solvent, a ketone-based organic solvent, an ether-based organic solvent and an ester-based organic solvent, more preferably at least one member selected from the group consisting of a ketone-based organic solvent and an ester-based organic solvent, more preferably a ketone-based organic solvent.

The molecular weight of the non-fluorinated organic solvent is, in view of more excellent solubility of the fluorinated ether compound, preferably 30 to 500, more preferably 40 to 400, further preferably 50 to 300.

Particularly, the non-fluorinated organic solvent is preferably acetone, ethyl acetate, methanol, toluene, methyl acetate, methyl ethyl ketone, propyl acetate or butyl acetate, more preferably acetone, ethyl acetate, methyl ethyl ketone or propyl acetate.

The non-fluorinated organic solvent may be used singly or in combination of 2 or more.

The content of the non-fluorinated organic solvent in the present treatment agent is preferably 60 mass % or more, more preferably 75 to 99.999 mass %, further preferably 85 to 99.99 mass %, particularly preferably 90 to 99.9 mass %.

In the present treatment agent, in view of more excellent uniformity at the time of film forming, the ratio of the content of the non-fluorinated organic solvent to the content of the present compound is preferably 60 to 99.999 mass %, more preferably 90 to 99.99 mass %, further preferably 95 to 99.9 mass %.

### Other Component

The present treatment agent may contain components other than the present compound and the non-fluorinated organic solvent within a range not to impair the effects of the present invention.

Such other components include fluorinated compounds other than the present compound, the following impurities, and known additives such as acid catalysts and basic catalysts that promote hydrolysis and condensation reaction of the hydrolysable silyl group.

The content of such other components in the present treatment agent is preferably 10 mass % or less, more preferably 1 mass % or less. The lower limit may be 0 mass %.

Examples of other fluorinated compounds include fluorinated organic solvents, fluorinated compounds formed as by-products in the process for producing the present compound (hereinafter sometimes referred to as by-product fluorinated compounds), and known fluorinated compounds used for the same application as the present compound.

Such other fluorinated compounds are preferably compounds that will hardly impair properties of the present compound.

The present treatment agent may contain a fluorinated organic solvent.

Examples of the fluorinated organic solvent include a fluorinated alkane, a fluorinated aromatic compound, a fluoroalkyl ether, a fluorinated alkylamine, a fluoroalcohol and a hydrofluoroolefin.

The fluorinated alkane is preferably a C₄₋₈ compound. Examples of commercial products include C₆F₁₃H (manufactured by AGC Inc., ASAHIKLIN (registered trademark) AC-2000), C₆F₁₃C₂H₅ (manufactured by AGC Inc., ASAHIKLIN (registered trademark) AC-6000), and C₂F₅CHFCHFCF₃ (manufactured by Chemours, Vertrel (registered trademark) XF).

Examples of the fluorinated aromatic compound include hexafluorobenzene, trifluoromethylbenzene, perfuorotoluene and bis(trifluoromethyl)benzene.

The fluoroalkyl ether is preferably a C₄₋₁₂ compound. Examples of commercial products include CF₃CH₂OCF₂CF₂H (manufactured by AGC Inc., ASAHIKLIN (registered trademark) AE-3000), C₄F₉OCH₃ (manufactured by 3M, Novec (registered trademark) 7100), C₄F₉OC₂H₅ (manufactured by 3M, Novec (registered trademark) 7200), and C₂F₅CF(OCH₃)C₃F₇ (manufactured by 3M, Novec (registered trademark) 7300).

Examples of the fluorinated alkylamine include perfluorotripropylamine and perfluorotributylamine.

Examples of the fluoroalcohol include 2,2,3,3-tetrafluoropropanol, 2,2,2-trifluoroethanol and hexafluoroisopropanol.

Specific examples of the hydrofluoroolefin include 1-chloro-2,3,3-trifluoro-1-propene (HCFO-1233 yd), a reaction product of methanol with 1,1,1,2,2,3,4,5,5,6,6,7,7,7-tetradecafluoro-3-heptene, and a reaction product of methanol with 1,1,1,2,3,4,4,5,5,6,6,7,7,7-tetradecafluoro-3-heptene. Commercial products include AMOLEA (registered trademark) AS-300 manufactured by AGC Inc., and Opteon (registered trademark) (SF01, SF05, SF10, SF30, SF33, SF70, SF79, SF80) manufactured by Chemours.

Examples of the by-product fluorinated compound include an unreacted fluorinated compound at the time of synthesis of the present compound. In a case where the present treatment agent contains the by-product fluorinated compound, a step of removing the by-product fluorinated compound or a purification step to reduce the amount of the by-product fluorinated compound can be simplified.

Examples of the known fluorinated compound include compounds described in the following documents.

Perfluoropolyether-modified aminosilanes as described in JP-A-H11-029585,
silicon-containing organic fluorinated polymers as described in Japanese Patent No. 2874715,
organic silicon compounds as described in JP-A-2000-144097,
perfluoropolyether-modified aminosilanes as described in JP-A-2000-327772,
fluorinated siloxanes as described in JP-A-2002-506887,
organic silicone compounds as described in JP-A-2008-534696,
fluorinated modified hydrogen-containing polymers as described in Japanese Patent No. 4138936,
compounds as described in US Patent Application No. 2010/0129672, WO2014/126064 and JP-A-2014-070163,
organosilicon compounds as described in WO2011/060047 and WO2011/059430,
fluorinated organosilane compounds as described in WO2012/064649,
fluorooxyalkylene group-containing polymers as described in JP-A-2012-72272,
fluorinated ether compounds as described in WO2013/042732, WO2013/121984, WO2013/121985, WO2013/121986, WO2014/163004, JP-A-2014-080473, WO2015/087902, WO2017/038830, WO2017/038832 and WO2017/187775,
perfluoro(poly)ether-containing silane compounds as described in JP-A-2014-218639, WO2017/022437, WO2018/079743 and WO2018/143433,
fluoropolyether group-containing polymer-modified silane as described in JP-A-2015-199906, JP-A-2016-204656, JP-A-2016-210854 and JP-A-2016-222859, and
fluorinated ether compounds as described in WO2018/216630, WO2019/039226, WO2019/039341, WO2019/039186, WO2019/044479, JP-A-2019-44158 and WO2019/163282.

Commercial products of the fluorinated compound include KY-100 series (KY-178, KY-185, KY-195, etc.) manufactured by Shin-Etsu Chemical Co., Ltd., SURECO (registered trademark) AF series such as SURECO 2101S, manufactured by AGC Inc., Optool (registered trademark) DSX, Optool (registered trademark) AES, Optool (registered trademark) UF503, Optool (registered trademark) UD509 etc. manufactured by DAIKIN INDUSTRIES, LTD.

In a case where the present treatment agent contains other fluorinated compounds, the proportion of other fluorinated compounds to the total amount of the present compound and the other fluorinated compounds is preferably 40 mass % or less, more preferably 30 mass % or less, further preferably 20 mass % or less. The lower limit may be 0 mass %.

The proportion of the present compound to the total amount of the present compound and the other fluorinated compound in the present treatment agent is preferably 80 mass % or more, more preferably 85 mass % or more. The upper limit may be 100 mass %.

When the contents of the present compound and the other fluorinated compounds are within the above ranges, the obtainable surface layer will be excellent in water/oil repellency, abrasion resistance, fingerprint stain removability, lubricity and appearance.

The impurities include compounds inevitable in production of the present compound and in production of the other fluorinated compounds.

The present treatment agent is suitably used as a coating liquid. The present treatment agent, when used as a coating liquid, may be a solution or a dispersion so long as it is liquid.

The total concentration of components other than the non-fluorinated organic solvent and the fluorinated organic solvent in the present treatment agent (hereinafter sometimes referred to as “solid content concentration”) is preferably 0.001 to 40 mass %, more preferably 0.01 to 20 mass %, further preferably 0.01 to 10 mass %, particularly preferably 0.01 to 1 mass %.

The solid content concentration of the surface treatment agent is a value calculated from the mass of the surface treatment agent before heating and the mass of the surface treatment agent after heated in a convection drier at 120° C. for 4 hours.

### Article

The article of the present invention (hereinafter sometimes referred to as “present article”) has a substrate and a surface layer disposed on the substrate and preferably has a primer layer between the substate and the surface layer.

The surface layer is a layer formed of the above surface treatment agent and contains a condensate of the fluorinated ether compound.

The material and the shape of the substrate may properly be selected depending upon e.g. the application of the present article. As the material of the substrate, for example, glass, a resin, sapphire, a metal, a ceramic, a stone or a composite material thereof may be mentioned. The glass may be chemically tempered. Particularly, as a substrate which is required to have water/oil repellency, a substrate for a touch panel, a substrate for a display, a substrate constituting a casing of an electronic device, and the like may be mentioned. The substrate for a touch panel and the substrate for a display has optical transparency. “Having optical transparency” means the normal incidence visible light transmittance in accordance with JIS R3106:1998 (ISO 9050:1990) of 25% or more. As a material of the substrate for a touch panel, glass or a transparent resin is preferred.

The substrate may have a surface treatment such as corona discharge treatment, plasma treatment or plasma graft polymerization treatment applied to the surface on which the primary layer is to be formed. The surface-treated surface of the substrate has more excellent adhesion to the primary layer and as a result the surface layer will have more improved abrasion resistance. The surface treatment is preferably corona discharge treatment or plasma treatment, whereby the surface layer will be more excellent in abrasion resistance.

The primary layer is preferably a layer containing a silicon-containing oxide (preferably silicon oxide) and may further contain another element. By the primary layer containing silicon oxide, the reactive silyl group of the fluorinated ether compound undergoes dehydration condensation to form a Si—O—Si bond with the primary layer, whereby a surface layer excellent in abrasion resistance will be formed.

The content of silicon oxide in the primary layer is preferably 65 mass % or more, more preferably 80 mass % or more, further preferably 85 mass % or more, particularly preferably 90 mass % or more. When the content of silicon oxide is equal to the lower limit value or more, the Si—O—Si bond will be formed in a sufficient amount in the primary layer, and sufficient mechanical properties of the primary layer will be secured. The content of silicon oxide is the remainder after subtracting the total content of the other elements (as calculated as oxides in the case of oxides) from the mass of the primary layer.

In view of the durability of the surface layer, the oxide in the primary layer preferably further contains at least one element selected from the group consisting of an alkali metal elements, an alkaline earth metal elements, a platinum group elements, boron, aluminum, phosphorus, titanium, zirconium, iron, nickel, chromium, molybdenum and tungsten. By the oxide containing such an element, the bond between the primary layer and the fluorinated ether compound becomes strong, and abrasion resistance will improve.

The thickness of the primary layer is preferably 1 to 200 nm, more preferably 2 to 20 nm. When the thickness of the primary layer is equal to the lower limit value or more, sufficient effects of improving the adhesion by the primary layer is obtained. When the thickness of the primary layer is equal to the upper limit value or less, the abrasion resistance of the primary layer itself is high. As a method of measuring the thickness of the primary layer, for example, a method of observing the cross section of the primary layer by an electron microscope (e.g. SEM, TEM), or a method using an optical interference membrane thickness meter, a spectral ellipsometer or a profilometer may be mentioned.

As a method of forming the primary layer, for example, a method of depositing a deposition material having a composition of the desired primary layer on the surface of a substrate may be mentioned.

As the deposition method, as an example, vacuum deposition method may be mentioned. The vacuum deposition method is a method of evaporating the deposition material in a vacuum chamber and let the deposition material be deposited on the surface of the substrate.

The temperature at the time of deposition (for example, in a case where a vacuum deposition apparatus is used, the temperature of a boat on which the deposition material is placed) is preferably 100 to 3,000° C., more preferably 500 to 3,000° C.

The pressure at the time of deposition (for example, in a case where a vacuum deposition apparatus is used, the absolute pressure in a chamber in which the deposition material is placed) is preferably 1 Pa or less, more preferably 0.1 Pa or less.

In a case where the primary layer is formed by using the deposition material, a single type of the deposition material may be used, or 2 or more types of deposition materials containing different elements may be used.

As a method of evaporating the deposition material, an electric resistance heating method of melting and evaporating the deposition material on an electric resistance heating boat made of a high melting point metal, an electron gun method of irradiating the deposition material with an electron beam to directly heat the deposition material thereby to melt the surface and to evaporate the deposition material, and the like may be mentioned. As the method of evaporating the deposition material, preferred is the electron gum method, whereby local heating is possible and thus a high melting point substance can also be evaporated, and a portion not irradiated with an electron beam remains low temperature and thus no risk of reaction with a container and inclusion of impurities is involved. The deposition material used for the electron gun method is preferably in the form of molten particles or a sintered product, which is less likely to fly even if an air current occurs.

The surface layer contains a condensate of the fluorinated ether compound. The condensate of the fluorinated ether compound has a structure such that the hydrolysable silyl group in the fluorinated ether compound is hydrolyzed to form a silanol group (Si—OH), which undergoes intermolecular condensation reaction to form a Si—O—Si bond, and a structure such that the silanol group in the fluorinated ether compound undergoes condensation reaction with a silanol group or a Si—OM group (wherein M is an alkali metal elements) on the surface of the substrate or the primary layer to form a Si—O—Si bond. The surface layer may contain a condensate of a fluorinated compound other than the fluorinated ether compound. That is, the surface layer contains a fluorinated compound having a reactive silyl group in a state where a part of or the whole of reactive silyl groups of the fluorinated compound has undergone condensation reaction.

The thickness of the surface layer is preferably 1 to 100 nm, more preferably 1 to 50 nm. When the thickness of the surface layer is equal to the lower limit value or more, effects by the surface layer will sufficiently be obtained. When the thickness of the surface layer is equal to the upper limit value or less, high utilization efficiency will be achieved.

The thickness of the surface layer is the thickness obtained by an X-ray diffractometer for thin film analysis. The thickness of the surface layer may be calculated from the period of oscillation of an interference pattern of reflected X-rays obtained by an X-ray diffractometer for thin film analysis by X-ray reflectometry.

The present article is preferably a touch panel. In this case, the surface layer is formed preferably on the surface of a member constituting a surface of the touch panel to be touched with fingers.

### Method for Producing Article

The method for producing the present article is a method of forming a surface layer on a substrate using the present treatment agent by dry coating method or wet coating method.

The present treatment agent is suitably used for wet coating method. Examples of the wet coating method include spin coating method, wipe coating method, spray coating method, squeegee coating method, dip coating method, die coating method, ink jetting method, flow coating method, roll coating method, casting method, Langmuir-Blodgett method and gravure coating method.

The present treatment agent may be used for dry coating method. As the dry coating method, vacuum deposition, CVD, sputtering or the like may be employed. With a view to suppressing decomposition of the fluorinated ether compound and in view of apparatus simplicity, vacuum deposition method is suitable.

For vacuum deposition, a pelletized substance having the fluorinated ether compound and the metal compound supported on a metal porous body of iron, steel or the like, is used. The pelletized substance having the fluorinated ether compound and the metal compound supported can be produced by impregnating the metal porous body with the present treatment agent, followed by drying to remove the liquid medium.

In order to improve abrasion resistance of the surface layer, as the case require, an operation to promote the reaction of the fluorinated ether compound with the substrate (or the primary layer) may be conducted. Such an operation may, for example, be heating, humidification or irradiation with light. For example, the substrate having the surface layer formed thereon may be heated in the air containing moisture, whereby hydrolysis of the hydrolysable group, reaction of the hydroxy group or the like on the surface of the substrate with the silanol group, formation of a siloxane bond by condensation reaction of the silanol group, or the like, may be promoted.

After the surface treatment, compounds that are in the surface layer and that are not chemically bonded to another compound or the substrate may be removed as the case requires. Specific examples include a method of pouring a solvent on the surface layer and a method of wiping the surface layer with cloth impregnated with a solvent.

### EXAMPLES

Now, the present invention will be described in further detail with reference to Examples. However, it should be understood that the present invention is by no means restricted to such specific Examples. Hereinafter, “%” means “mass %” unless otherwise specified. Examples 1 to 14 are Examples of the present invention, and Examples 15 to 18 are Comparative Examples.

### Synthesis of Compound 1

### Synthesis Example 1-1

The following Compound 1 was obtained in accordance with Synthesis Examples 3 and 4 of WO2018/143433.

CF₃O(CF₂CF₂O)₂₁(CF₂O)₂₉CF₂CONHCH₂C[CH₂CH₂CH₂Si(OCH₃)₃]₃

### Synthesis of Compound 2

### Synthesis Example 2-1

Into a reactor, 2.1 g of methyl cyanoacetate, 11.9 g of 11-bromo-1-undecene (CH₂═CH(CH₂)₉—Br), 11.2 g of potassium carbonate and 52.5 g of N,N-dimethylformamide (DMF) were put and stirred in a nitrogen atmosphere at 85° C. After completion of the reaction, hydrochloric acid was added, an organic phase was recovered, and the recovered organic phase was concentrated by an evaporator to obtain 8.1 g of the following Compound (2-1).

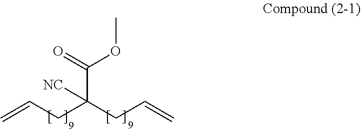

### Synthesis Example 2-2

Into a reactor, 8.1 g of the above Compound (2-1), 24.3 g of dimethyl sulfoxide (DMSO), 3.0 g of lithium chloride and 4.7 g of water were put and stirred in a nitrogen atmosphere at 180° C. After completion of the reaction, hydrochloric acid was added, an organic phase was recovered, and the recovered organic phase was concentrated by an evaporator and subjected to silica gel column chromatography to obtain 6.2 g of the following Compound (2-2).

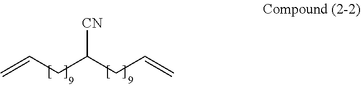

### Synthesis Example 2-3

Into a reactor, 3.0 g of lithium aluminum hydride and 27.0 g of dehydrated tetrahydrofuran (THF) were put and stirred in a nitrogen atmosphere at 0° C. Then, 5.4 g of the above Compound (2-2) was put and stirred in a nitrogen atmosphere at 0° C. After completion of the reaction, water and 1N sodium hydroxide were added, an organic phase was recovered, and the recovered organic phase was concentrated by an evaporator and subjected to silica gel column chromatography to obtain 4.3 g of the following Compound (2-3).

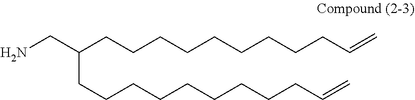 [SMILES: C=CCCCCCCCCCC(CN)CCCCCCCCCC=C]

### Synthesis Example 2-4

The following Compound (2-4) was obtained in accordance with the method in Examples (6-1) to (6-4) of WO2013/121984.

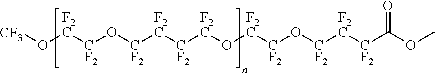

In the formula, the average value of the number n of repeating units is 13.

### Synthesis Example 2-5

Into a reactor, 15 g of the above Compound (2-4), 15 g of 1,3-bis(trifluoromethyl)benzene and 2.8 g of the above Compound (2-3) were put and stirred in a nitrogen atmosphere at 60° C. After completion of the reaction, the reaction mixture was washed, concentrated by an evaporator and subjected to silica gel column chromatography to obtain 11.4 g of the following Compound (2-5).

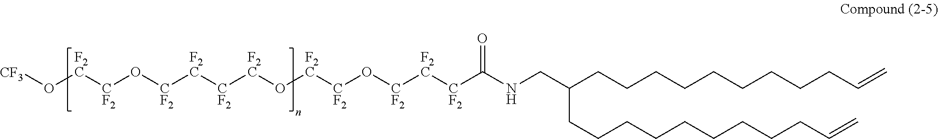

In the formula, the average value of the number n of repeating units is 13.

### Synthesis Example 2-6

Into a reactor the interior of which was replaced with nitrogen, 5.0 g of the above Compound (2-5), 5.0 g of 1,3-bis(trifluoromethyl)benzene, 0.21 g of a xylene solution of a platinum/1,3-divinyl-1,1,3,3-tetramethyldisiloxane complex (platinum content: 2%), 0.48 g of HSi(OCH₃)₃ and 0.04 g of DMSO were put and stirred at 40° C. After completion of the reaction, the solvent and the like were distilled off under reduced pressure, and the reaction mixture was subjected to filtration through a membrane filter with an aperture of 0.2 μm to obtain 5.1 g of the following Compound 2.

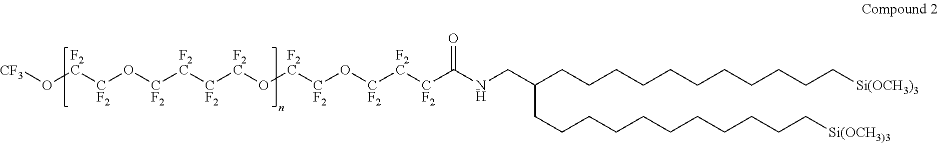

In the formula, the average value of the number n of repeating units is 13.

### Synthesis of Compound 3

### Synthesis Example 3-1

Into a reactor, 2.0 g of dimethyl malonate, 10.6 g of 11-bromo-1-undecene (CH₂═CH(CH₂)₉—Br), 8.4 g of potassium carbonate and 50.0 g of DMF were put and stirred in a nitrogen atmosphere at 85° C. After completion of the reaction, hydrochloric acid was added, and the organic phase was recovered, which was concentrated by an evaporator to obtain 6.1 g of the following Compound (3-1).

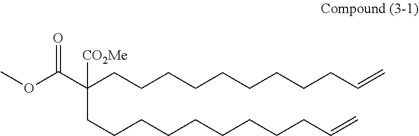 [SMILES: C=CCCCCCCCCCC(CCCCCCCCCC=C)(C(=O)OC)C(=O)OC]

### Synthesis Example 3-2

Into a reactor, 6.1 g of the above Compound (3-1), 24.4 g of DMSO, 2.4 g of lithium chloride and 3.27 g of water were put and stirred in a nitrogen atmosphere at 180° C. After completion of the reaction, hydrochloric acid was added, an organic phase was recovered, and the recovered organic phase was concentrated by an evaporator and subjected to silica gel column chromatography to obtain 4.0 g of the following Compound (3-2).

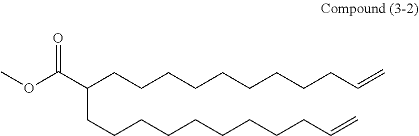 [SMILES: C=CCCCCCCCCCC(CCCCCCCCCC=C)C(=O)OC]

### Synthesis Example 3-3

Into a reactor, 2.9 g of the above Compound (3-2), 52.98 g of ethanol and 8.6 g of potassium hydroxide were put and stirred in a nitrogen atmosphere at 120° C. After completion of the reaction, hydrochloric acid was added, an organic phase was recovered, and the recovered organic phase was concentrated by an evaporator and subjected to silica gel column chromatography to obtain 2.5 g of the following Compound (3-3).

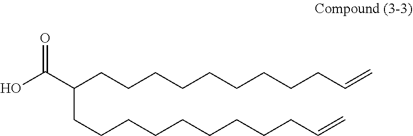 [SMILES: C=CCCCCCCCCCC(CCCCCCCCCC=C)C(=O)O]

### Synthesis Example 3-4

Into a reactor, 2.5 g of the above Compound (3-3), 25 g of dichloromethane, 2.6 g of oxalyl chloride and 0.04 g of DMF were put and stirred in a nitrogen atmosphere at room temperature (25° C.). After completion of the reaction, the reaction mixture was concentrated by an evaporator to obtain 2.6 g of the following Compound (3-4).

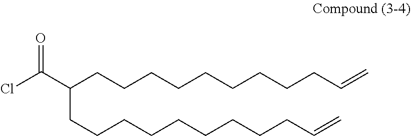 [SMILES: C=CCCCCCCCCCC(CCCCCCCCCC=C)C(=O)Cl]

### Synthesis Example 3-5

The following Compound (3-5) was obtained in accordance with the method in Examples (1-1) to (1-3) of WO2021/131960.

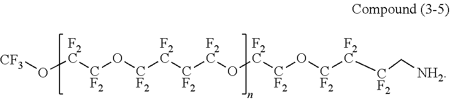

In the formula, the average value of the number n of repeating units is 13.

### Synthesis Example 3-6

Into a reactor, 10.0 g of the above Compound (3-5), 1.6 g of the above Compound (3-4) and 10 g of 1,3-bis(trifluoromethyl)benzene were put and stirred in a nitrogen atmosphere at 40° C. After completion of the reaction, the reaction mixture was concentrated by an evaporator and subjected to silica gel column chromatography to obtain 5.2 g of the following Compound (3-6).

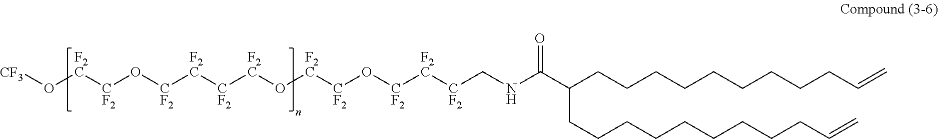

In the formula, the average value of the number n of repeating units is 13.

### Synthesis Example 3-7

Into a reactor the interior of which was replaced with nitrogen, 2.0 g of the above Compound (3-6), 2.0 g of 1,3-bis(trifluoromethyl)benzene, 0.09 g of a xylene solution of a platinum/1,3-divinyl-1,1,3,3-tetramethyldisiloxane complex (platinum content: 2%), 0.19 g of HSi(OCH₃)₃ and 0.02 g of DMSO were put and stirred at 40° C. After completion of the reaction, the solvent and the like were distilled off under reduced pressure, and the reaction mixture was subjected to filtration through a membrane filter with an aperture of 0.2 μm to obtain 2.0 g of the following Compound 3.

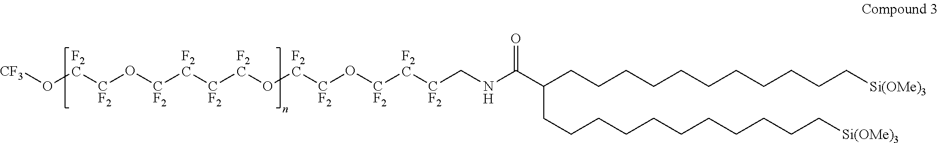

In the formula, the average value of the number n of repeating units is 13.

### Synthesis of Compound 4

### Synthesis Example 4-1

Into a reactor, 2.1 g of methyl cyanoacetate, 7.1 g of 7-bromo-1-heptene, 11.2 g of potassium carbonate and 50 g of N,N-dimethylformamide were put and stirred at 85° C. overnight (24 hours). Then, the reaction mixture was cooled to room temperature (25° C.), hydrochloric acid was added, and extraction with dichloromethane was conducted. The solvent was distilled off to obtain 5.5 g of the following Compound (4-1).

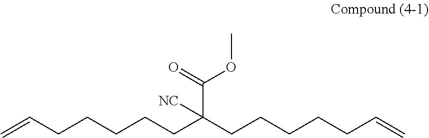 [SMILES: C=CCCCCCC(C#N)(CCCCCC=C)C(=O)OC]

¹H-NMR (400 MHz, Chloroform-d) δ (ppm): 5.92 to 5.74 (m, 2H), 5.13 to 4.90 (m, 4H), 3.8 (s, 3H), 1.90 to 2.20 (m, 4H), 1.90 to 1.0 (m, 16H)

### Synthesis Example 4-2

Into a reactor, 5.5 g of the above Compound (4-1) and 30 g of DMSO were put and stirred, and 5 g of water and 3.2 g of lithium chloride were further added. The mixture was heated to 180° C. and stirred at 180° C. overnight (24 hours). The mixture was cooled to room temperature (25° C.), extraction with dichloromethane was conducted, the solvent was distilled off, and flash column chromatography by silica gel (developing solvent: ethyl acetate/hexane) was conducted to obtain 4.4 g of the following Compound (4-2).

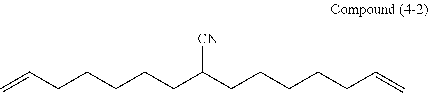 [SMILES: C=CCCCCCC(C#N)CCCCCC=C]

¹H-NMR (400 MHz, Chloroform-d) δ (ppm): 5.92 to 5.74 (m, 2H), 5.13 to 4.90 (m, 4H), 2.41 to 2.62 (m, 1H), 1.95 to 2.20 (m, 4H), 1.90 to 1.0 (m, 16H)

### Synthesis Example 4-3

Into a reactor, 2.3 g of the above Compound (4-2) and 20 mL of dehydrated THF were added, 6.0 mL of a THF solution (12.5 mmol) of lithium diisopropylamide was further added, followed by stirring at −70° C. for 15 minutes. 2.0 g of 7-bromo-1-heptene was added to the reactor and stirred at room temperature (25° C.) overnight. Hydrochloric acid was added to the reactor, extraction with dichloromethane was conducted, and the solvent was distilled off to obtain 2.9 g of the following Compound (4-3).

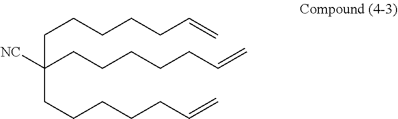 [SMILES: C=CCCCCCC(C#N)(CCCCCC=C)CCCCCC=C]

¹H-NMR (400 MHz, Chloroform-d) δ (ppm): 5.92 to 5.70 (m, 3H), 5.13 to 4.8 (m, 6H), 1.95 to 2.20 (m, 6H), 1.90 to 1.0 (m, 24H)

### Synthesis Example 4-4

In a reactor, 2.9 g of the above Compound (4-3) was dissolved in 20 ml of dehydrated THF, and the solution was cooled to 0° C. 12 mL (12 mmol) of a THF solution of lithium aluminum hydride was added to the reactor and stirred. Water and a 15% aqueous sodium hydroxide solution were further added and stirred at room temperature (25° C.), and the mixture was diluted with dichloromethane. The mixture was subjected to filtration, the solvent was distilled off, and flash column chromatography by silica gel (developing solvent: methanol) was conducted to obtain 2.0 g of the following Compound (4-4).

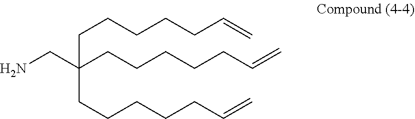 [SMILES: C=CCCCCCC(CN)(CCCCCC=C)CCCCCC=C]

¹H-NMR (400 MHz, Chloroform-d) δ (ppm): 5.92 to 5.70 (m, 3H), 5.13 to 4.8 (m, 6H), 2.40 to 2.60 (s, 2H), 1.95 to 2.20 (m, 6H), 1.90 to 1.0 (m, 24H)

### Synthesis Example 4-5

Into a reactor, 10 g of the above Compound (2-4) and 10 g of AC-2000 were added, and 1.1 g of the above Compound (4-4) was added. The mixture was stirred at 40° C. overnight (24 hours) and subjected to column chromatography by silica gel (developing solvent: C₆F₁₃H (manufactured by AGC Inc., ASAHIKLIN (registered trademark) AC-2000)/CF₃CH₂OCF₂CF₂H (manufactured by AGC Inc., ASAHIKLIN AE-3000) to obtain 7.0 g of the following Compound (4-5).

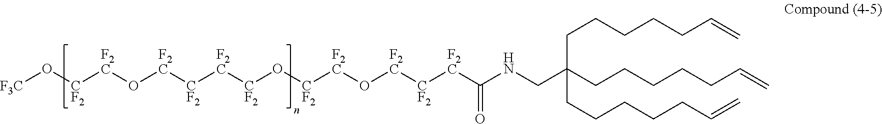

In the formula, the average value of the number n of repeating units is 13.

¹H-NMR (400 MHz, Chloroform-d) δ (ppm): 6.44 to 6.21 (1H), 5.89 to 5.61 (m, 3H), 5.11 to 4.55 (6H), 3.49 to 3.23 (m, 2H), 2.11 to 1.81 (m, 6H), 1.52 to 1.02 (24H)

¹⁹F-NMR (376 MHz, Chloroform-d) δ (ppm): −55.3, −82.8, −88.0, −90.2, −119.4, −125.2, −125.6

### Synthesis Example 4-6

Into a reactor, 1.0 g of AC-6000, 0.5 g of the above Compound (4-5), 8.3 mg of a toluene solution of a platinum/1,3-divinyl-1,1,3,3-tetramethyldisiloxane complex (platinum content: 3%), 2.6 mg of aniline and 0.25 g of trimethoxysilane were added and stirred at 40° C. The solvent was distilled off under reduced pressure to obtain 0.52 g of the following Compound 4.

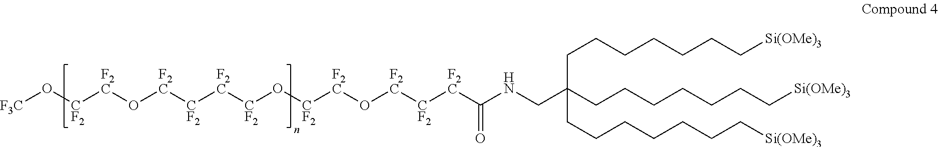

In the formula, the average value of the number n of repeating units is 13.

¹H-NMR (400 MHz, Chloroform-d) δ (ppm): 6.44 to 6.21 (1H), 3.51 to 4.01 (m, 27H), 3.25 to 3.50 (2H), 1.58 to 1.02 (36H), 0.92 to 0.57 (6H)

¹⁹F-NMR (376 MHz, Chloroform-d) δ (ppm): −55.3, −82.8, −88.0, −90.2, −119.4, −125.2, −125.6

### Synthesis of Compound 5

### Synthesis Example 5-1

Into a reactor, 3.0 g of 3,4-dimethylbenzonitrile, 8,14 g of N-bromosuccinimide, 0.74 g of benzoyl peroxide and 44.6 g of 1,2-dichloroethane were put and stirred in a nitrogen atmosphere at 85° C. After completion of the reaction, the formed solids were removed by filtration, and the recovered organic phase was concentrated by an evaporator and subjected to silica gel column chromatography to obtain 3.5 g of the following Compound (5-1).

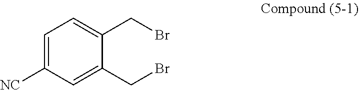 [SMILES: N#Cc1ccc(CBr)c(CBr)c1]

### Synthesis Example 5-2

Into a reactor, 5.9 g of 11-bromo-1-undecene (CH₂═CH(CH₂)₉—Br), 0.65 g of powdery magnesium and 19.5 g of THF were put and stirred at 40° C. for 24 hours.

Then, 0.35 g of copper chloride, 3.5 g of the above Compound (5-1) and 21.0 g of THF were added and stirred at 45° C. After completion of the reaction, hydrochloric acid was added, an organic phase was recovered, and the recovered organic phase was concentrated by an evaporator and subjected to silica gel column chromatography to obtain 3.0 g of the following Compound (5-2).

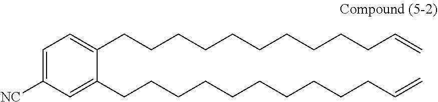 [SMILES: C=CCCCCCCCCCCc1ccc(C#N)cc1CCCCCCCCCCC=C]

### Synthesis Example 5-3

Into a reactor, 0.30 g of lithium aluminum hydride and 6.0 g of THF were put, 1.2 g of the above Compound (5-2) dissolved in 6.0 g of THF was slowly added dropwise to the reactor, followed by stirring at 25° C. After completion of the reaction, an aqueous sodium hydroxide solution was added, the formed solids were removed by filtration, and the recovered organic phase was concentrated by an evaporator and subjected to silica gel column chromatography to obtain 1.0 g of the following Compound (5-3).

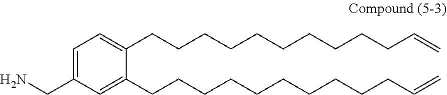 [SMILES: C=CCCCCCCCCCCc1ccc(CN)cc1CCCCCCCCCCC=C]

### Synthesis Example 5-4

The following Compound (2-4) was obtained in accordance with the method described in Examples (6-1) to (6-4) of WO2013/121984.

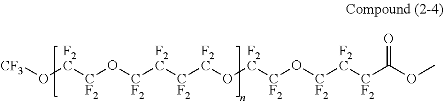

In the formula, the average value of the number n of repeating units is 13.

### Synthesis Example 5-5

Into a reactor, 3.3 g of the above Compound (2-4), 3.3 g of 1,3-bis(trifluoromethyl)benzene and 0.44 g of the above Compound (5-3) were put and stirred in a nitrogen atmosphere at 60° C. After completion of the reaction, the mixture was washed, concentrated by an evaporator and subjected to silica gel column chromatography to obtain 2.5 g of the following Compound (5-5).

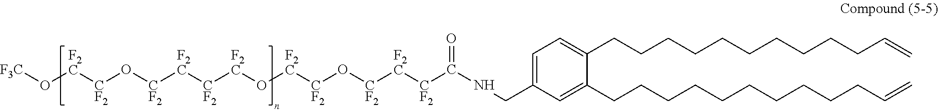

In the formula, the average value of the number n of repeating units is 13.

### Synthesis Example 5-6

Into a reactor the interior of which was replaced with nitrogen, 2.5 g of the above Compound (5-5), 2.5 g of 1,3-bis(trifluoromethyl)benzene, 0.11 g of a xylene solution of a platinum/1,3-divinyl-1,1,3,3-tetramethyldisiloxane complex (platinum content: 2%), 0.24 g of HSi(OCH₃)₃ and 0.02 g of DMSO were put and stirred at 40° C. After completion of the reaction, the solvent and the like were distilled off under reduced pressure, and the reaction mixture was subjected to filtration through a membrane filter with an aperture of 0.2 μm to obtain 2.5 g of the following Compound 5.

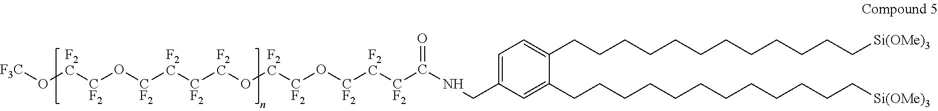

In the formula, the average value of the number n of repeating units is 13.

### Synthesis of Compound 6

The following Compound 6 was obtained in accordance with the method described in Synthesis Example 16-3 of WO2023/074874.

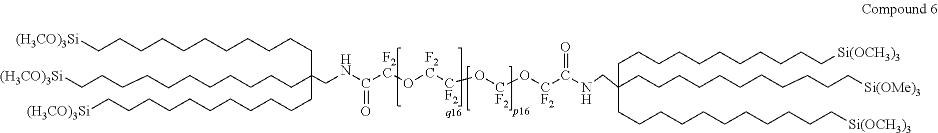

In the formula, the average value of the number q16 of repeating units is 21, and the average value of the number p16 of repeating units is 29.

### Example 1

The above Compound 2 and acetone as the liquid medium were mixed to prepare surface treatment agent 1.

### Example 2

Surface treatment agent 2 was prepared in accordance with the method described in Example 1 except that ethyl acetate (“Ethyl Acetate” manufactured by KANTO CHEMICAL CO., LTD.) was used instead of acetone as the liquid medium.

### Examples 3 to 4

Surface treatment agents 3 and 4 were respectively prepared in accordance with the methods described in Examples 1 and 2 except that the above Compound 3 was used instead of Compound 2 as the fluorinated ether compound.

### Examples 5 to 6

Surface treatment agents 5 and 6 were respectively prepared in accordance with the method described in Example 3 except that methanol (“Methanol” manufactured by KANTO CHEMICAL CO., LTD.) and toluene (“Toluene” manufactured by KANTO CHEMICAL CO., LTD.) were respectively used instead of acetone as the liquid medium.

### Examples 7 to 8

Surface treatment agents 7 and 8 were respectively prepared in accordance with the methods described in Examples 1 and 2 except that the above Compound 4 was used instead of Compound 2 as the fluorinated ether compound.

### Examples 9 to 10

Surface treatment agents 9 and 10 were respectively prepared in accordance with the methods described in Examples 1 and 2 except that the above Compound 5 was used instead of Compound 2 as the fluorinated ether compound.

### Examples 11 to 12

Surface treatment agents 11 and 12 were respectively prepared in accordance with the methods described in Examples 1 and 2 except that the above Compound 1 was used instead of Compound 2 as the fluorinated ether compound.

### Examples 13 to 14

Surface treatment agents 13 and 14 were respectively prepared in accordance with the methods described in Examples 1 and 2 except that the above Compound 6 was used instead of Compound 2 as the fluorinated ether compound.

### Example 16

Surface treatment agent 16 was prepared in accordance with the method described in Example 1 except that hydrofluoroalkyl ether (C₄F₉OC₂H₅, “Novec (registered trademark) HFE-7200” manufactured by 3M) was used instead of acetone as the liquid medium.

### Examples 15, 17 and 18

Surface treatment agents 15, 17 and 18 were respectively prepared in accordance with the method described in Example 16 except that Compounds 1, 3 and 4 were respectively used instead of Compound 2 as the fluorinated ether compound.

The content (solid content concentration) of the fluorinated ether compound in the surface treatment agent prepared in each of Examples 1 to 18 was 0.05%.

### Production and Evaluation of Article

### Wet Coating Method

Using each of the compounds in Examples 1 to 18, surface treatment was applied to a substrate to obtain an article having a surface layer. As the surface treatment method, the following wet coating method was conducted in each Example As the substrate, chemically tempered glass was used. The obtained article was subjected to evaluation by the following method. The results are shown in Table 1.

The substrate was dipped in the surface treatment agent (coating liquid) in each of Examples 1 to 18, left to stand for 30 minutes and taken out (dip coating method). The coating film was dried at 200° C. for 30 minutes and washed with AE-3000 to obtain an article having a surface layer formed on the surface of the substrate.

### Evaluation Methods

### Initial Water Contact Angle

The water contact angle of about 2 μL of distilled water placed on the surface of the surface layer was measured by a contact angle measuring apparatus (manufactured by Kyowa Interface Science Co., Ltd., DMo-701) in each Example Measurement was conducted on different five points on the surface of the surface layer, and the arithmetic mean of the obtained measured values was calculated. To calculate the contact angle, 2θ method was employed.

From the calculated contact angle, the initial water contact angle was evaluated based on the following evaluation standards.

The evaluation standards for the initial water contact angle are as follows.
A (excellent): 110° or more
B (good): 108° or more and less than 110°
C. (fail): less than 108°

### Abrasion Resistance

On the surface layer, steel wool BONSTAR (#0000) was reciprocated under a pressure of 98.07 kPa at 320 cm/min for 30,000 cycles using a reciprocating traverse testing machine (manufactured by KNT) in accordance with JIS L0849:2013 (ISO 105-X12:2001), and then the water contact angle was measured. The abrasion resistance was evaluated based on the following evaluation standard from the difference in the water contact angle between before and after the abrasion test. A small decrease in water repellency (water contact angle) by the abrasion test indicates a small decrease of the performance due to abrasion and excellent abrasion resistance.

The evaluation standards for abrasion resistance are as follows.
A (good): change of water contact angle before and after 30,000 cycles of within 5°
B (acceptable): change of water contact angle before and after 30,000 cycles of more than 5° and 10° or less
C: (fail): change of water contact angle before and after 30,000 cycles of more than 10°

### Solubility

With respect to each surface treatment agent, solubility of the fluorinated ether compound was measured by the following method.

500 g of each liquid medium was added to 0.5 g of the fluorinated ether compound, and the mixture was stirred in a 1 L eggplant flask at 25° C. for 1 hour. After the stirring for 1 hour, the stirring was stopped, and the mixture was left at rest for 24 hours. Then, the mixture was visually observed and the solubility was evaluated based on the following evaluation standards.

The evaluation standards for solubility are as follows.
A (good): no precipitate confirmed in the solution, and uniform solution was obtained.
B (acceptable): no precipitate confirmed but white turbidity observed.
C (fail): precipitate confirmed.

In Table 1 are shown the composition and the evaluation results of each surface treatment agent.

In Table 1, the “non-F moiety partial structure molecular weight” row indicates the molecular weight of a partial structure corresponding to the group represented by L¹-(R¹¹-T¹¹)ₓ₁ in the formula (A1), in each of the above Compounds 1 to 4.

In Table 1, the “PFPE molecular weight” raw indicates the molecular weight of a partial structure corresponding to the group represented by (OR^{f11})_{y1} in the formula (A1), in each of the above Compounds 1 to 4.

In Table 1, the “non-F moiety partial structure molecular weight ratio (mass %)” row indicates the ratio of the molecular weight of a partial structure corresponding to the group represented by [R^{f1}-(OR^{f11})_{y1}-O-R¹]ⱼ to the molecular weight of a partial structure corresponding to the group represented by L¹-(R¹¹-T¹¹)ₓ₁ in the formula (A1), in each of the above Compounds 1 to 4.

In Table 1, “HFE” means a hydrofluoroalkyl ether.

TABLE 1

| | | Example | | | | | | | | |
|---|---|---|---|---|---|---|---|---|---|---|
| | | 1 | 2 | 3 | 4 | 5 | 6 | 7 | 8 | 9 |
| Fluorinated | Type | 2 | 2 | 3 | 3 | 3 | 3 | 4 | 4 | 5 |
| ether | Content (mass %) | 0.05 | 0.05 | 0.05 | 0.05 | 0.05 | 0.05 | 0.05 | 0.05 | 0.05 |
| compound | Non-F moiety partial | 621 | 621 | 817 | 817 | 817 | 817 | 727 | 727 | 711 |
| | structure molecular weight | | | | | | | | | |
| | PFPE molecular weight | 4,500 | 4,500 | 4,500 | 4,500 | 4,500 | 4,500 | 4,500 | 4,500 | 4,500 |
| | Non-F moiety partial | 14 | 14 | 18 | 18 | 18 | 18 | 16 | 16 | 16 |
| | structure molecular weight | | | | | | | | | |
| | ratio (mass %) | | | | | | | | | |
| Liquid | Type | Acetone | Ethyl | Acetone | Ethyl | Methanol | Toluene | Acetone | Ethyl | Acetone |
| medium | | | acetate | | acetate | | | | acetate | |
| Evaluation | Initial water contact angle | A | A | A | A | A | A | A | A | A |
| | Abrasion resistance | A | A | A | A | B | B | A | A | A |
| | Solubility | A | A | A | A | A | A | A | A | A |
| | | Example | | | | | | | | |
| | | 10 | 11 | 12 | 13 | 14 | 15 | 16 | 17 | 18 |
| Fluorinated | Type | 5 | 1 | 1 | 6 | 6 | 1 | 2 | 3 | 4 |
| ether | Content (mass %) | 0.05 | 0.05 | 0.05 | 0.05 | 0.05 | 0.05 | 0.05 | 0.05 | 0.05 |
| compound | Non-F moiety partial | 711 | 559 | 559 | 1,791 | 1,791 | 559 | 621 | 817 | 727 |
| | structure molecular weight | | | | | | | | | |
| | PFPE molecular weight | 4,500 | 4,500 | 4,500 | 4,500 | 4,500 | 4,500 | 4,500 | 4,500 | 4,500 |
| | Non-F moiety partial | 16 | 12 | 12 | 40 | 40 | 12 | 14 | 18 | 16 |
| | structure molecular weight | | | | | | | | | |
| | ratio (mass %) | | | | | | | | | |
| Liquid | Type | Ethyl | Acetone | Ethyl | Acetone | Ethyl | HFE | HFE | HFE | HFE |
| medium | | acetate | | acetate | | acetate | | | | |
| Evaluation | Initial water contact angle | A | A | A | A | A | A | A | A | A |
| | Abrasion resistance | A | B | B | A | A | C | C | C | C |
| | Solubility | A | B | B | A | A | A | A | A | A |

As shown in Table 1, it was confirmed that a surface layer excellent in abrasion resistance could be formed from the surface treatment agent containing the fluorinated ether compound represented by any of the formulae (A1) to (A3), in which the molecular weight of the organic group containing a reactive silyl group is equal to a predetermined value or more, and an organic solvent containing no fluorine atom (Examples 1 to 14).

### INDUSTRIAL APPLICABILITY

The article having a surface layer formed of the surface treatment agent of the present invention is useful, for example, as an optical article, a touch panel, an antireflection film, an antireflection glass, a SiO₂-treated glass, a tempered glass, a sapphire glass, a quartz substrate or a mold metal, used as a part of a member of the following products.

Products: car navigations, mobile phones, digital cameras, digital video cameras, portable digital assistants (PDA), portable audio players, car audios, gaming machines, glasses lens, camera lenses, lens filters, sunglasses, medical devices (such as gastrocameras), copying machines, personal computers (PC), liquid crystal displays, organic EL displays, plasma displays, touch panel displays, protective films, antireflection films, antireflection glasses, nanoimprinting templates, molds, etc.

This application is a continuation of PCT Application No. PCT/JP2023/036908, filed on Oct. 11, 2023, which is based upon and claims the benefit of priority from Japanese Patent Application No. 2022-164739 filed on Oct. 13, 2022. The contents of those applications are incorporated herein by reference in their entireties.

What is claimed is:

1. A surface treatment agent containing at least one fluorinated ether compound selected from the group consisting of a compound represented by the following formula (A1), a compound represented by the following formula (A2) and a compound represented by the following formula (A3), and an organic solvent containing no fluorine atom;
[R^{f1}-(OR^{f11})_{y1}-O-R¹]ⱼ-L¹-(R¹¹-T¹¹)ₓ₁ (A1)
(T³¹-R³¹)ₓ₃-L³-R³-(OR^{f12})_{y2}-O-R²-L²-(R²¹-T²¹)ₓ₂ (A2)
Q¹[-(OR^{f13})_{y3}-O-R⁴-L⁴-(R⁴¹-T⁴¹)ₓ₄]ᵣ₁ (A3)
in the formula (A1),
R^{f1} is a C₁₋₂₀ fluoroalkyl group, and when there is a plurality of R^{f1}, the plurality of R^{f1} may be the same or different from each other,
R^{f11} is a C₁₋₆ fluoroalkylene group, and when there is a plurality of R^{f11}, the plurality of R^{f11} may be the same or different from each other,
R¹ is an alkylene group or a fluoroalkylene group, and when there is a plurality of R¹, the plurality of R¹ may be the same or different from each other,
L¹ is a single bond or a (j+x1)-valent group which may have N, O, S or Si and may have a branch point, and in which atoms bonded to R¹ and R¹¹ are each independently N, O, S, Si, a carbon atom constituting the branch point, or a carbon atom having a hydroxy group or an oxo group,
R¹¹ is an alkylene group in which an atom bonded to L¹ may be an etheric oxygen atom, and which may have an etheric oxygen atom between carbon atoms, and when there is a plurality of R¹¹, the plurality of R¹¹ may be the same or different from each other,
T¹¹ is a group represented by -SiR^{a11}_{z11}R^{a12}_{3-z11}, and when there is a plurality of T¹¹, the plurality of T¹¹ may be the same or different from each other,
R^{a11} is a hydroxy group or a hydrolysable group, and when there is a plurality of R^{a11}, the plurality of R^{a11} may be the same or different from each other,
R^{a12} is a non-hydrolysable group, and when there is a plurality of R^{a12}, the plurality of R^{a12} may be the same or different from each other,
j is an integer of 1 or more, and when j is 1, y1 is an integer of 2 or more, or R¹ is a fluoroalkylene group,
z11 is an integer of 1 to 3,
x1 is an integer of 1 or more,
y1 is an integer of 1 or more, and when there is a plurality of y1, the plurality of y1 may be the same or different from each other, and
the group represented by L¹-(R¹¹-T¹¹)ₓ₁ has a molecular weight of 600 or more,
in the formula (A2),
R^{f12} is a C₁₋₆ fluoroalkylene group, and when there is a plurality of R^{f12}, the plurality of R^{f12} may be the same or different from each other,
R² and R³ are each independently an alkylene group or a fluoroalkylene group,
L² is a single bond or a (1+x2)-valent group which may have N, O, S or Si and may have a branch point, and in which atoms bonded to R² and R²¹ are each independently N, O, S, Si, a carbon atom constituting the branch point, or a carbon atom having a hydroxy group or an oxo group,
L³ is a single bond or a (1+x3)-valent group which may have N, O, S or Si and may have a branch point, and in which atoms bonded to R³ and R³¹ are each independently N, O, S, Si, a carbon atom constituting the branch point, or a carbon atom having a hydroxy group or an oxo group,
R²¹ is an alkylene group in which an atom adjacent to L² may be an etheric oxygen atom, and which may have an etheric oxygen atom between carbon atoms, and when there is a plurality of R²¹, the plurality of R²¹ may be the same or different from each other,
R³¹ is an alkylene group in which an atom adjacent to L³ may be an etheric oxygen atom, and which may have an etheric oxygen atom between carbon atoms, and when there is a plurality of R³¹, the plurality of R³¹ may be the same or different from each other,
T²¹ and T³¹ are each independently -SiR^{a21}_{z21}R^{a22}_{3-z21}, when there is a plurality of T²¹, the plurality of T²¹ may be the same or different from each other, and when there is a plurality of T³¹, the plurality of T³¹ may be the same or different from each other,
R^{a21} is a hydroxy group or a hydrolysable group, and when there is a plurality of R^{a21}, the plurality of R^{a21} may be the same or different from each other,
R^{a22} is a non-hydrolysable group, and when there is a plurality of R^{a22}, the plurality of R^{a22} may be the same or different from each other,
z21 is an integer of 1 to 3,
x2 and x3 are each independently an integer of 1 or more,
y2 is an integer of 1 or more, and when y2 is 1, R² is a fluoroalkylene group, and
at least one of the group represented by L²-(R²¹-T²¹)ₓ₂ and the group represented by (T³¹-R³¹)ₓ₃-L³ has a molecular weight of 600 or more,
in the formula (A3),
Q¹ is a r1-valent group having a branch point,
R^{f13} is a C₁₋₆ fluoroalkylene group, and when there is a plurality of R^{f13}, the plurality of R^{f13} may be the same or different from each other,
R⁴ is each independently an alkylene group or a fluoroalkylene group, and the plurality of R⁴ may be the same or different from each other,
L⁴ is a single bond or a (1+x4)-valent group which may have N, O, S or Si and may have a branch point, and in which atoms bonded to R⁴ and R⁴¹ are each independently N, O, S, Si, a carbon atom constituting the branch point, or a carbon atom having a hydroxy group or an oxo group, and the plurality of L⁴ may be the same or different from each other,
R⁴¹ is an alkylene group in which an atom adjacent to L⁴ may be an etheric oxygen atom, and which may have an etheric oxygen atom between carbon atoms, and the plurality of R⁴¹ may be the same or different from each other,
T⁴¹ is -SiR^{a41}_{z41}R^{a42}_{3-z41}, and the plurality of T⁴¹ may be the same or different from each other,
R^{a41} is a hydroxy group or a hydrolysable group, and the plurality of R^{a41} may be the same or different from each other,
R^{a42} is a non-hydrolysable group, and when there is a plurality of R^{a42}, the plurality of R^{a42} may be the same or different from each other,
z41 is an integer of 1 to 3,
x4 is an integer of 1 or more, and when there is a plurality of x4, the plurality of x4 may be the same or different from each other,
y3 is an integer of 1 or more, and when there is a plurality of y3, the plurality of y3 may be the same or different from each other,
r1 is 3 or 4, and
at least one group represented by L⁴-(R⁴¹-T⁴¹)ₓ₄ has a molecular weight of 600 or more.

2. The surface treatment agent according to claim 1, wherein
at least one R¹¹ has a carbon chain having 5 or more carbon atoms linked to one another,
at least one of R²¹ and R³¹ has a carbon chain having 5 or more carbon atoms linked to one another, and
at least one R⁴¹ has a carbon chain having 5 or more carbon atoms linked to one another.

3. The surface treatment agent according to claim 1, wherein
at least one R¹¹ has a carbon chain having 5 to 18 carbon atoms linked to one another,
at least one of R²¹ and R³¹ has a carbon chain having 5 to 18 carbon atoms linked to one another, and
at least one R⁴¹ has a carbon chain having 5 to 18 carbon atoms linked to one another.

4. The surface treatment agent according to claim 1, wherein
the alkylene group as R¹¹ is a linear alkylene group,
the alkylene group as R²¹ and R³¹ is a linear alkylene group, and
the alkylene group as R⁴¹ is a linear alkylene group.

5. The surface treatment agent according to claim 1, wherein
the group represented by (OR^{f11})_{y1} has a molecular weight of 2,000 to 10,000,
the group represented by (OR^{f12})_{y2} has a molecular weight of 2,000 to 10,000, and
the group represented by (OR^{f13})_{y3} has a molecular weight of 2,000 to 10,000.

6. The surface treatment agent according to claim 1, wherein
a ratio of a molecular weight of the group represented by [R^{f1}-(OR^{f11})_{y1}-O-R¹]ⱼ to a molecular weight of the group represented by L¹-(R¹¹-T¹¹)ₓ₁ is 13% or more,
a ratio of a molecular weight of the group represented by R³-(OR^{f12})_{y2}-O-R² to a sum of a molecular weight of the group represented by L²-(R²¹-T²¹)ₓ₂ and a molecular weight of the group represented by (T³¹-R³¹)ₓ₃-L³ is 13% or more, and
a ratio of a sum of a sum of molecular weights of r1 pieces of groups represented by (OR^{f13})_{y3}-O-R⁴ and a molecular weight of the group represented by Q¹, to a sum of molecular weights of r1 pieces of groups represented by L⁴-(R⁴¹-T⁴¹)ₓ₄, is 13% or more.

7. The surface treatment agent according to claim 1, wherein the organic solvent containing no fluorine atom contains at least one member selected from the group consisting of a ketone-based solvent and an ester-based solvent.

8. The surface treatment agent according to claim 1, wherein a ratio of a content of the organic solvent containing no fluorine atom to a content of the fluorinated ether compound is 60 to 99.999 mass %.

9. An article having a surface layer formed of the surface treatment agent as defined in claim 1 on the surface of a substrate.

10. A method for producing an article, which comprises forming a surface layer using the surface treatment agent as defined in claim 1 by dry coating method or wet coating method.
